(19) United States
(12) Patent Application Publication
(10) Pub. No.: US 2025/0063908 A1
(43) Pub. Date: Feb. 20, 2025

(54) STRETCHABLE DISPLAY APPARATUS AND METHOD OF MANUFACTURING THE SAME

(71) Applicant: Samsung Display Co., Ltd., Yongin-Si (KR)

(72) Inventors: Woosuk Seo, Yongin-si (KR); Taeho Lee, Yongin-si (KR)

(21) Appl. No.: 18/807,892

(22) Filed: Aug. 16, 2024

(30) Foreign Application Priority Data
Aug. 18, 2023 (KR) 10-2023-0108258

(51) Int. Cl. H10K 59/131; H10K 59/12; H10K 102/00

(52) U.S. Cl. CPC H10K 59/131; H10K 59/1201; H10K 2102/311

(57) ABSTRACT

Provided are a stretchable display apparatus including a display area and a non-display area NDA outside the display area and a method of manufacturing the stretchable display apparatus, wherein the stretchable display apparatus includes a plurality of island portions arranged in the display area and disposed to be spaced apart from one another, a plurality of bridge portions each connecting island portions adjacent to each other among the plurality of island portions, and a plurality of wirings arranged in the plurality of bridge portions, and each of the wirings includes a first layer including an alloy of aluminum and a rare-earth element.

### CROSS-REFERENCE TO RELATED APPLICATION

This application is based on and claims priority under 35 U.S.C. § 119 to Korean Patent Application No. 10-2023-0108258, filed on Aug. 18, 2023, in the Korean Intellectual Property Office, the disclosure of which is incorporated by reference herein in its entirety.

### BACKGROUND

### 1. Field

One or more embodiments relate to a flexible display apparatus, e.g., a stretchable display apparatus, and a method of manufacturing the same.

### 2. Description of the Related Art

Due to the development of display apparatuses configured to visually display electrical signals, various kinds of display apparatuses having excellent characteristics such as thin and lightweighted, and low power consumption have been introduced. For example, flexible display apparatuses that may be folded or rolled have been introduced. Recently, there has been ongoing research and development of stretchable display apparatuses that may be transformed into various shapes.

### SUMMARY

One or more embodiments relate to a flexible display apparatus, for example, a stretchable display apparatus. However, the technical goal is only an example, and the scope of the embodiments is not limited thereto.

Additional aspects will be set forth in part in the description which follows and, in part, will be apparent from the description, or may be learned by practice of the presented embodiments of the disclosure.

According to one or more embodiments, a stretchable display apparatus, which includes a display area and a non-display area outside the display area, includes a plurality of island portions arranged in the display area and disposed to be spaced apart from one another, a plurality of bridge portions each connecting adjacent island portions from among the plurality of island portions, and a plurality of wirings arranged in the bridge portions, wherein each of the wirings includes a first layer including an alloy of aluminum and a rare-earth element.

The first layer may include an amorphous alloy layer.

The rare-earth element may include at least one of yittrium (Y), samarium (SM), cerium (Ce), and lanthanium (La).

A content of the rare-earth element may be at least 4 at % but not more than 10 at % with respect to a total atomic weight of the first layer.

A content of the aluminum may be at least 90 at % but not more than 96 at % with respect to the total atomic weight of the first layer.

A resistivity of the first layer may be at least 10 μΩ·cm but not more than 50 μΩ·cm.

An elastic limit of the first layer may be at least 2.0% but not more than 3.0%.

A yield strength of the first layer may be at least 1.0 GPa but not more than 1.5 Gpa.

Each of the plurality of wirings may further include a second layer disposed under the first layer and a third layer disposed over the first layer, the second layer and the third layer may include a material different from a material of the first layer, and the second layer and the third layer may include a same material.

Each of the island portions may include a transistor including a semiconductor and a gate electrode, an emission element electrically connected to the transistor, and an electrode disposed between the gate electrode and the emission element, and the electrode may include an alloy layer of aluminum and a rare-earth element.

According to one or more embodiments, a method of manufacturing a stretchable display apparatus including a display area and a non-display outside the display area includes forming a plurality of island portions, arranged in the display area and disposed to be spaced apart from one another, and a plurality of bridge portions each connecting adjacent island portions from among the plurality of island portions, and forming a plurality of wirings arranged in the plurality of bridge portions, wherein the forming of the plurality of wirings includes forming a first layer including an alloy of aluminum and a rare-earth element by a sputtering method.

The forming of the first layer may include forming a mother alloy including aluminum and the rare-earth element, forming power of the mother alloy, forming an alloy body by sintering the powder, and depositing the first layer on a substrate by sputtering using the alloy body as a target.

The first layer may include an amorphous alloy layer.

The rare-earth element may include at least one of yittrium (Y), samarium (SM), cerium (Ce), and lanthanium (La).

A content of the rare-earth element may be at least 4 at % but not more than 10 at % with respect to a total atomic weight of the first layer.

A content of the aluminum may be at least 90 at % but not more than 96 at % with respect to the total atomic weight of the first layer.

A temperature of the substrate may be at least RT but not more than 150° C.

The sputtering may be performed at a power density of at least 4 W/cm² but not more than 5 W/cm².

An elastic limit of the first layer may be at least 2.0% but not more than 3.0%.

A yield strength of the first layer may be at least 1.0 GPa but not more than 1.5 GPa.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view schematically illustrating a stretchable display apparatus according to an embodiment;

FIGS. 2A and 2B are perspective views each illustrating a state in which the stretchable display apparatus shown in FIG. 1 is stretched in a first direction;

FIG. 2C is a perspective view illustrating a state in which the stretchable display apparatus shown in FIG. 1 is stretched in a second direction;

FIG. 2D is a perspective view illustrating a state in which the stretchable display apparatus shown in FIG. 1 is stretched in the first direction and the second direction.

FIG. 2E is a perspective view illustrating a state in which the stretchable display apparatus shown in FIG. 1 is stretched in a third direction;

FIG. 3 is a plan view schematically illustrating a stretchable display apparatus according to an embodiment;

FIG. 4A is an enlarged plan view of a portion IV shown in FIG. 3 as a portion of a stretchable display apparatus according to an embodiment;

FIG. 4B is an enlarged plan view of the portion IV shown in FIG. 3 as a portion of a stretchable display apparatus according to an embodiment;

FIG. 4C is an enlarged plan view of the portion IV shown in FIG. 3 as a portion of the stretchable display apparatus according to an embodiment;

FIG. 5 is a cross-sectional view schematically illustrating a first island portion and a first bridge portion arranged in a display area of a stretchable display apparatus according to an embodiment;

FIGS. 6A, 6B and 6C are equivalent circuit diagrams of a subpixel of a stretchable display apparatus according to an embodiment;

FIGS. 7A and 7B are cross-sectional views each schematically illustrating an emission element of a stretchable display apparatus according to an embodiment;

FIG. 8A is an enlarged plan view of a first island portion of a stretchable display apparatus according to an embodiment;

FIG. 8B is a plan view illustrating an arrangement of wirings on a first bridge portion of a stretchable display apparatus according to an embodiment;

FIG. 9 illustrates a cross-section taken along a line I-I′ shown in FIG. 8A and a cross-section taken along a line II-II′ shown in FIG. 8B;

FIG. 10 is a cross-sectional view of a wiring or a connection electrode of a stretchable display apparatus which includes an alloy layer according to an embodiment;

FIGS. 11A and 11B are cross-sectional views of a wiring or connection electrode including an alloy layer of a stretchable display apparatus according to another embodiment;

FIG. 12 is a flowchart showing a method of manufacturing an alloy layer according to an embodiment;

FIG. 13 illustrates a result of X-ray diffraction (XRD) analysis of an alloy layer according to an embodiment;

FIGS. 14 and 15 are graphs each showing a result of measuring resistivity of an alloy layer according to an embodiment;

FIG. 16 illustrates a microstructure of an alloy layer according to an embodiment;

FIG. 17 illustrates a fine structure of an alloy layer according to an embodiment;

FIG. 18 shows a microstructure and results of XRD analysis of an alloy layer according to a comparative embodiment;

FIG. 19 is a graph showing results of a tensile test of an alloy layer according to an embodiment; and

FIGS. 20A, 20B, 20C, 20D, 20E, 20F and 20G are perspective views each schematically illustrating an embodiment of an electronic device including a stretchable display apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As used herein, the terms ‘first’ and ‘second’ are only used to distinguish one element from others, and are not used in a limited sense.

As used herein, the singular forms are intended to encompass the plural forms as well, unless the context clearly indicates otherwise.

It will be further understood that the terms “comprise,” “comprising,” “include,” “including,” “have,” “having,” and the like, when used herein, specify the presence of stated features and/or elements, but do not preclude the presence or addition of one or more other features and/or elements.

In the following embodiments, when a portion such as a film, an area, or a component is on or above another portion, the portion may be directly on the other portion, or other films, areas, or components may be located therebetween.

In the drawings, the sizes of elements may be exaggerated or reduced for convenience. For example, since the size and thickness of each element is arbitrarily shown in the drawings for convenience of description, the disclosure is not necessarily limited to those illustrated.

When some embodiments may be differently implemented, a particular process sequence may be performed differently from a sequence described. For example, two processes described in succession may be performed substantially simultaneously, or may be performed in an order opposite to an order described.

In the present specification, when it is referred that a film, an area, and a component are connected to another film, area, and component, the film, area, and component may be directly connected to the other film, area, and component, or may be indirectly connected with another film, area, and component therebetween. For example, when it is referred that a film, an area, and a component are electrically connected to another film, area, and component, the film, area, and component may be directly in electric connection with the other film, area, and component, or may be indirectly in electric connection with the other film, area, and component with another film, area, and component therebetween.

An x-axis, a y-axis, and a z-axis are not limited to three axes on an orthogonal coordinate system, and may be interpreted as a wide meaning including the same. For example, the x-axis, y-axis, and z-axis may be orthogonal to one another, but may also refer to different directions that are not orthogonal to one another.

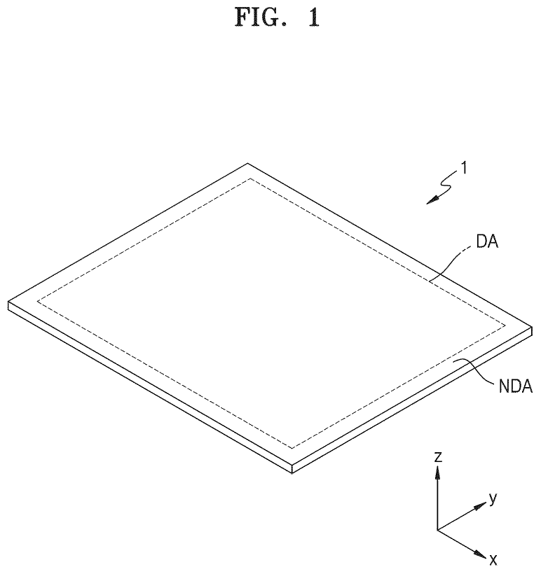

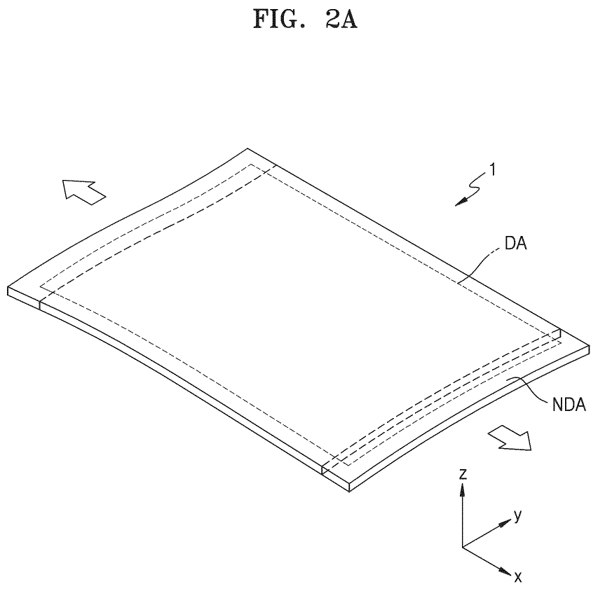

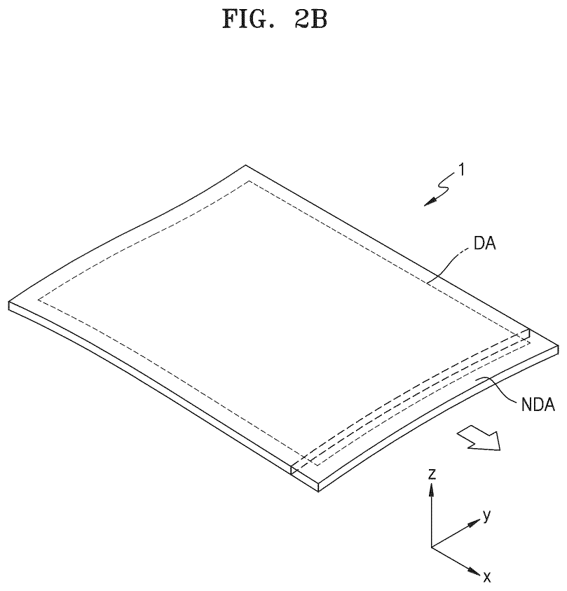

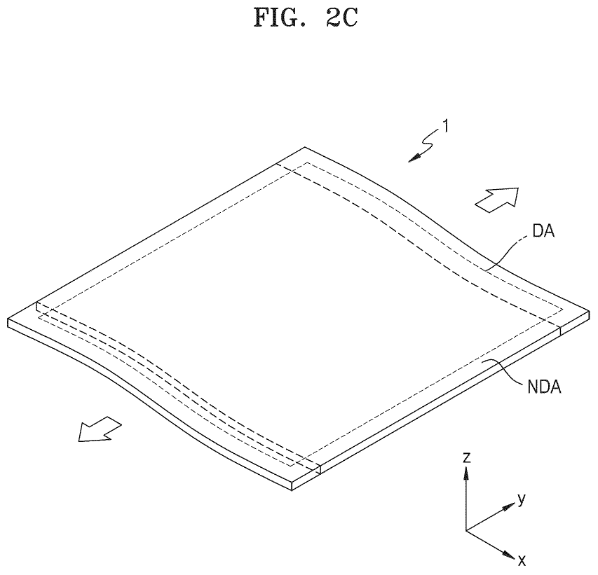

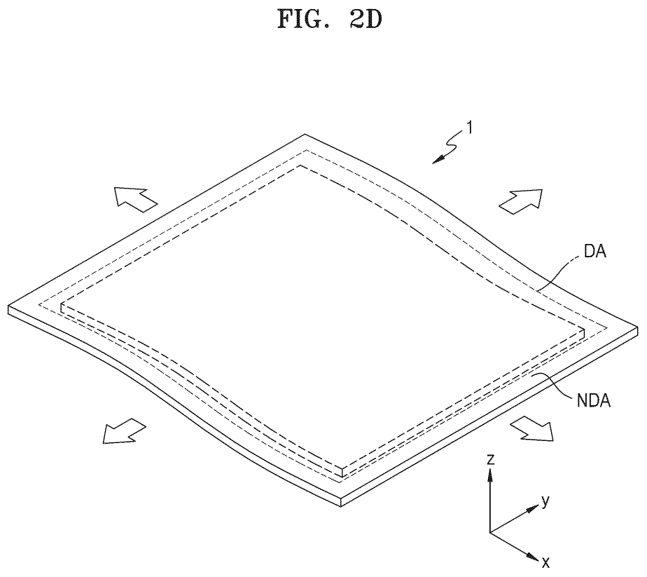

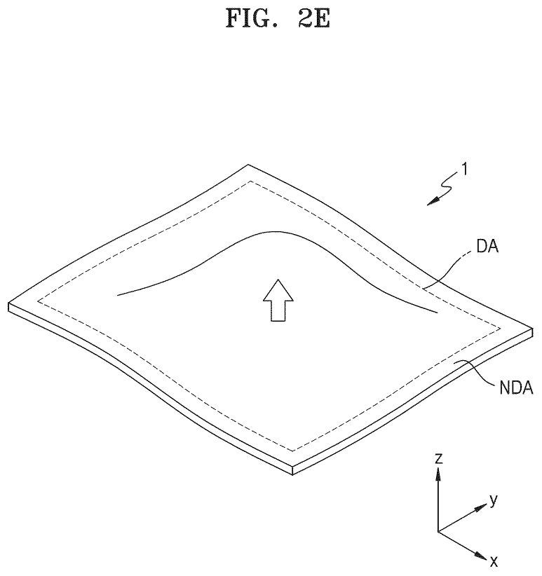

FIG. 1 is a perspective view schematically illustrating a stretchable display apparatus 1 according to an embodiment. FIGS. 2A and 2B are perspective views each illustrating a state in which the stretchable display apparatus 1 shown in FIG. 1 extends in a first direction. FIG. 2C is a perspective view illustrating a state in which the stretchable display apparatus 1 shown in FIG. 1 extends in a second direction. FIG. 2D is a perspective view illustrating a state in which the stretchable display apparatus 1 shown in FIG. 1 extends in the first direction and the second direction. FIG. 2E is a perspective view illustrating a state in which the stretchable display apparatus 1 shown in FIG. 1 extends in a third direction.

Referring to FIG. 1, the stretchable display apparatus 1 may include a display area DA and a non-display area NDA. The display area DA may include a plurality of pixels. The stretchable display apparatus 1 may be configured to provide certain images by using light emitted from the plurality of pixels. The non-display area NDA may be arranged outside the display area DA. The non-display area NDA may generally surround the display area DA.

The stretchable display apparatus 1 may extend or shrink in various directions. The stretchable display apparatus 1 may extend in the first direction (e.g., a x direction and/or a −x direction) by an external force applied by a foreign object or a user. For example, as shown in FIGS. 2A and 2B, the display area DA and/or the non-display area NDA of the stretchable display apparatus 1 may extend in the first direction (e.g., the x direction and/or the −x direction). For example, the display area DA and/or the non-display area NDA may extend in the x direction and the −x direction as shown in FIG. 2A, or may extend in the x direction in a state where a side of the stretchable display apparatus 1 is fixed as shown in FIG. 2B.

The stretchable display apparatus 1 may extend in the second direction (e.g., a y direction and/or a −y direction) by an external force applied by a foreign object or a user. In an embodiment, as shown in FIG. 2C, the display area DA and/or the non-display area NDA of the stretchable display apparatus 1 may extend in the y direction and the −y direction. In another embodiment, the display area DA and/or the non-display area NDA of the stretchable display apparatus 1 may extend in the y direction or the −y direction in a state where a side of the stretchable display apparatus 1 is fixed.

The stretchable display apparatus 1 may extend in a plurality of directions, e.g., the first direction (e.g., the x direction and/or the −x direction) and the second direction (e.g., the y direction and/or the −y direction) due to an external force applied by a foreign object or a part of a human body. As shown in FIG. 2D, the display area DA and/or the non-display area NDA of the stretchable display apparatus 1 may extend in the ±x directions and ±y directions.

The stretchable display apparatus 1 may extend in a third direction (e.g., a z direction or a −z direction) due to an external force applied by a foreign object or a part of a human body. In an embodiment, FIG. 2E illustrates that a portion of the stretchable display apparatus 1, e.g., an area of the display area DA, protrudes in the z direction. In another embodiment, a portion of the stretchable display apparatus 1, e.g., an area of the display area DA, may protrude in the −z direction (or may be recessed in the z direction).

Although FIGS. 2A to 2E illustrate that the stretchable display apparatus 1 extends in the first direction, the second direction, and/or the third direction, the disclosure is not limited thereto. In another embodiment, the stretchable display apparatus 1 may be variously deformed into amorphous shapes, for example, may be bent or twisted with two or more axes.

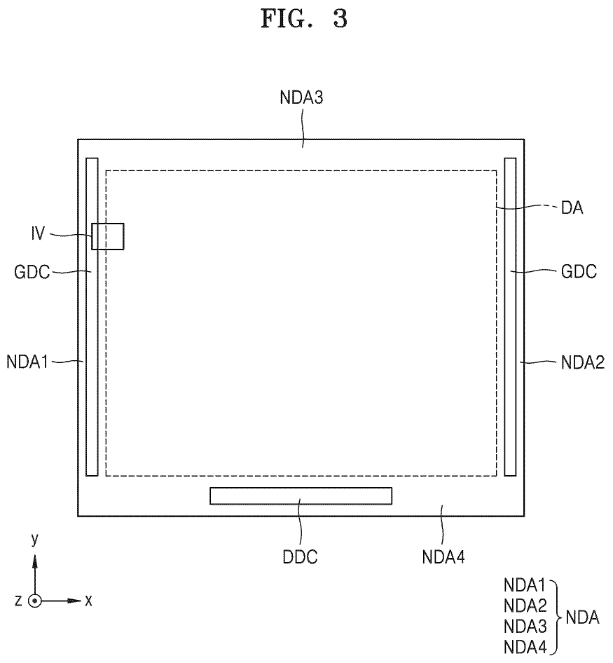

FIG. 3 is a plan view schematically illustrating the stretchable display apparatus 1 according to an embodiment.

The plurality of pixels may be arranged in the display area DA of the stretchable display apparatus 1. Each pixel may include sub-pixels respectively configured to emit light having different colors. Emission elements corresponding to the sub-pixels may be arranged in the display area DA. A circuit configured to provide electrical signals to the emission elements arranged in the display area DA and transistors electrically connected to the emission elements may be in the non-display area NDA near the display area DA. A gate driving circuit GDC may be arranged in each of a first non-display area NDA1 and a second non-display area NDA2 arranged at two sides of the display area DA. The gate driving circuit GDC may include drivers configured to provide electrical signals to gate electrodes of the transistors electrically connected to the emission elements. Although FIG. 3 illustrates that the gate driving circuit GDC is arranged in each of the first non-display area NDA1 and the second non-display area NDA2, the disclosure is not limited thereto. In another embodiment, the gate driving circuit GDC may be arranged in any one of the first non-display area NDA1 and the second non-display area NDA2.

A data driving circuit DDC may be arranged in a third non-display area NDA3 and/or a fourth non-display area NDA4 connecting the first non-display area NDA1 and the second non-display area NDA2. In an embodiment, FIG. 3 illustrates that the data driving circuit DDC is arranged in the fourth non-display area NDA4. In another embodiment, the data driving circuit DDC may be arranged in each of the third non-display area NDA3 and the fourth non-display area NDA4.

Although FIG. 3 illustrates that the data driving circuit DDC is arranged in the fourth non-display area NDA4 of the stretchable display apparatus 1, the disclosure is not limited thereto. In another embodiment, the stretchable display apparatus 1 may further include a flexible circuit board (not shown) electrically connected thereto through a terminal portion (not shown) arranged in the fourth non-display area NDA4, and the data driving circuit DDC may be arranged on the aforementioned flexible circuit board.

In some embodiments, an elongation rate of the non-display area NDA may not be more than an elongation rate of the display area DA. In an embodiment, the non-display area NDA may have different elongation rates according to areas. For example, although the first non-display area NDA1, the second non-display area NDA2, and the third non-display area NDA3 may have a substantially same elongation rate, an elongation rate of the fourth non-display area NDA4 may be less than the elongation rate of each of the first non-display area NDA1, the second non-display area NDA2, and the third non-display area NDA3.

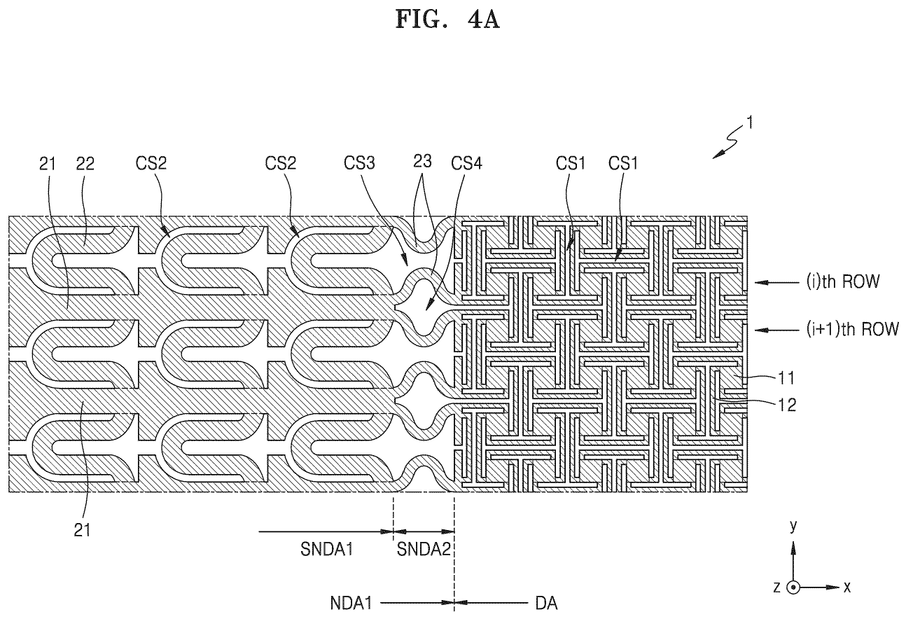

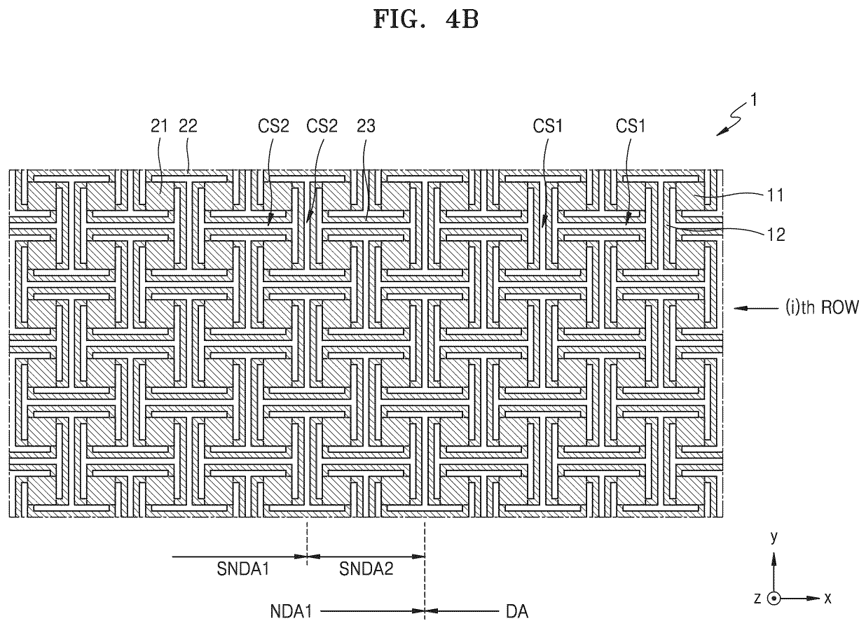

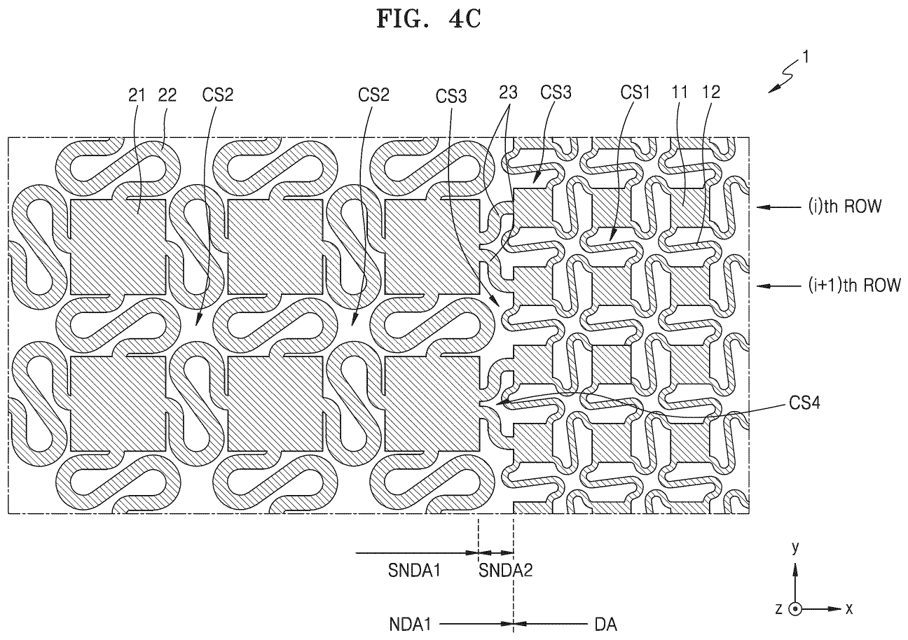

FIG. 4A is a plan view of an enlarged image of a portion IV shown in FIG. 3 as a portion of the stretchable display apparatus 1 according to an embodiment.

Referring to FIG. 4A, the stretchable display apparatus 1 may include: a plurality of first island portions 11 spaced apart from one another in the first direction (e.g., the x direction or the −x direction) and the second direction (e.g., the y direction or the −y direction) in the display area DA and a plurality of first bridge portions 12 each connecting first island portions 11 adjacent to each other.

Each of the plurality of first island portions 11 may be connected to the plurality of first bridge portions 12. For example, each of the plurality of first island portions 11 may be connected to four first bridge portions 12. Two first bridge portions 12 may be arranged at two sides of the first island portion 11 in the first direction (e.g., the x direction or the −x direction), and another two first bridge portions 12 may be arranged at two sides of the first island portion 11 in the second direction (e.g., the y direction or the −y direction). In an embodiment, four first bridge portions 12 may be respectively connected to four sides of a first island portion 11. Each of the four first bridge portions 12 may be connected to each of corners of the first island portion 11.

The first bridge portions 12 may be spaced apart from each other by a first opening CS1 disposed between the first bridge portions 12. In an embodiment, first opening portions CS1 having a shape approximately like the letter “H” and first opening portions CS1 having a shape approximately like the letter “I”, where the shape like the letter “I” is obtained by rotating the aforementioned shape like the letter “H” by 90 degrees, may be alternately and repeatedly arranged in the first direction (e.g., the x direction and the −x direction) and the second direction (e.g., the y direction or the −y direction). Two ends of each of the first bridge portions 12 may be respectively connected to the first island portions 11 adjacent to each other, and a side of each of the first bridge portions 12 may be spaced apart from a side of the first island portions 11 adjacent to each other and/or a side of another first bridge portion 12 by the first opening CS1.

In the non-display area NDA, e.g., the first non-display area NDA1 shown in FIG. 4A, the stretchable display apparatus 1 may include a plurality of second island portions 21 spaced apart from one another and a plurality of second bridge portions 22 each connecting second island portions 21 adjacent to each other.

Each of the plurality of second island portions 21 may extend in the first direction (e.g., the x direction or the −x direction). The plurality of second island portions 21 may be spaced apart from one another in the second direction (e.g., the y direction or the −y direction) crossing the first direction (e.g., the x direction or the −x direction). Each of the plurality of second island portions 21 may include drivers of the gate driving circuit GDC (see FIG. 3) described with reference to FIG. 3.

The second bridge portion 22 may have a serpentine shape. A length of the second bridge portion 22 may be greater than a minimum distance between the second island portions 21 disposed adjacent to each other in the second direction (e.g., the y direction or the −y direction). In an embodiment, the second bridge portion 22 may have a shape approximately like the Greek letter “Ω” of which a concave portion extends in the first direction (e.g., the x direction or the −x direction). The second bridge portions 22 may be arranged between the second island portions 21 disposed adjacent to each other, and may be spaced apart from each other.

The second bridge portions 22 disposed between the second island portions 21 adjacent to each other may be apart from each other by a second opening CS2. Between the second island portions 21 adjacent to each other, the second openings CS2 and the second bridge portions 22 may be alternately arranged in the first direction (e.g., the x direction or the −x direction). The second openings CS2 may have a same shape. Two end portions of each of the second bridge portions 22 may be connected to the second island portions 21 adjacent to each other, and a side of each of the second bridge portions 22 may be spaced apart from a side of the second island portions 21 disposed adjacent to each other and/or a side of another second bridge portion 22.

Any one of the second island portions 21 arranged in the first non-display area NDA1 may have a length corresponding to the first island portions 11 in a plurality of rows arranged in the display area DA. For example, any one of the second island portions 21 arranged in the first non-display area NDA1 may have the length corresponding to the first island portions 11 arranged in an (i)^{th} row and the first island portions 11 arranged in an (i+1)^{th} row (where i is a positive number). Although FIG. 4A illustrates that a second island portion 21 have the length corresponding to two rows of the first island portions 11, the disclosure is not limited thereto. In another embodiment, any one of the second island portions 21 arranged in the first non-display area NDA1 may have a length corresponding to n rows of the first island portions 11 arranged in the display area DA (where n is a positive number of 3 or greater).

The non-display area NDA, e.g., the first non-display area NDA1, may include: a first sub-non-display area SNDA1 in which the second island portions 21 and the second bridge portions 22 are arranged, and a second sub-non-display area SNDA2 disposed between the first sub-non-display area SNDA1 and the display area DA. A plurality of third bridge portions 23 to connect the display area DA and the first sub-non-display area SNDA1 may be arranged in the second sub-non-display area SNDA2. An end portion of the third bridge portion 23 may be connected to the second island portion 21 and/or the second bridge portion 22, and another end portion of the third bridge portion 23 may be connected to the first island portion 11 via the first bridge portion 12.

The third bridge portion 23 may have a serpentine shape. For example, a shape of the third bridge portion 23 may be different from shapes of the first bridge portion 12 and the second bridge portion 22. In an embodiment, as shown in FIG. 4A, the third bridge portion 23 may have a shape approximately like the Greek letter “Ω” of which a concave portion extends in the second direction (e.g., the y direction or the −y direction). The third bridge portions 23 disposed adjacent to each other and arranged in the second direction (e.g., the y direction or the −y direction) may have a symmetrical structure, e.g., one may be concave in the y direction, and another one may be concave in the −y direction. Third openings CS3 and fourth openings CS4 having different shapes may be repeatedly arranged between the third bridge portions 23. A width of the third bridge portion 23 may be different from a width of the first bridge portion 12 and a width of the second bridge portion 22. In an embodiment, the width of the third bridge portion 23 may be greater than the width of the first bridge portion 12 and less than the width of the second bridge portion 22.

FIG. 4A illustrates the second island portion 21 and the second bridge portion 22 in the non-display area NDA, e.g., the first non-display area NDA1, have shapes different from the shapes of the first island portion 11 and the first bridge portion 12 in the display area DA. According to another embodiment, the second island portion 21 and the second bridge portion 22 in the non-display area NDA may have shapes identical to the shapes of the first island portion 11 and the first bridge portion 12 in the display area DA.

FIG. 4B is a plan view of an enlarged image of the portion IV shown in FIG. 3 as a portion of the stretchable display apparatus 1 according to an embodiment.

Referring to FIG. 4B, the stretchable display apparatus 1 includes the first island portions 11 spaced apart from each other in the display area DA and the first bridge portions 12 spaced apart from each other by the first opening CS1 and each connecting the first island portions 11 adjacent to each other. A structure of the display area DA shown in FIG. 4B may be identical to a structure of the display area DA described above with reference to FIG. 4A.

The stretchable display apparatus 1 may include the second island portions 21 and the second bridge portions 22 arranged in the non-display area NDA, e.g., the first non-display area NDA1. In an embodiment, the second island portions 21 and the second bridge portions 22 may have shapes substantially identical to the shapes of the first island portions 11 and the first bridge portions 12.

The second island portions 21 may be spaced apart from each other in the first direction (e.g., the x direction and the-x direction) and the second direction (e.g., the y direction and the −y direction) in the non-display area NDA, e.g., the first non-display area NDA1. Each of the second bridge portions 22 may connect the second island portions 21 disposed adjacent to each other. The second bridge portions 22 may be spaced apart from each other by the second opening CS2 disposed between the second bridge portions 22.

The second opening CS2 may have a shape substantially identical to the shape of the first opening CS1. For example, the second openings CS2 having the shape approximately like the letter “H” and the second opening CS2 having the shape approximately like the letter “I” may be alternately and repeatedly arranged in the non-display area NDA, e.g., the first non-display area NDA1. Two end portions of each of the second bridge portions 22 may be connected to the second island portions 21 connected thereto, and a side of each of the second bridge portion 22 may be spaced apart from a side of the second island portion 21 adjacent to each other and/or a side of another second bridge portion 22 by the second opening CS2.

Each of the second island portions 21 may be connected to four second bridge portions 22. Each of the second island portions 21 may include the gate driving circuit GDC (see FIG. 3) described with reference to FIG. 3.

The second island portions 21 in any one row arranged in the first non-display area NDA1 may correspond to the first island portions 11 in any one row arranged in the display area DA. For example, the second island portions 21 arranged in the (i)^{th} row in the first direction (e.g., the x direction or the −x direction) in the first non-display area NDA1 may correspond to the first island portions 11 arranged in a same row, e.g., the (i)^{th} row, in the display area DA (where i is a positive number).

The stretchable display apparatus 1 may include the third bridge portions 23 arranged in the second sub-non-display area SNDA2 to connect the display area DA and the first sub-non-display area SNDA1. The non-display area NDA, e.g., the first non-display area NDA1, may include the first sub-non-display area SNDA1 in which the second island portions 21 and the second bridge portions 22 are arranged, and the second sub-non-display area SNDA2 including the third bridge portions 23 and disposed between the first sub-non-display area SNDA1 and the display area DA. The third bridge portion 23 may be substantially identical to the first bridge portion 12 and the second bridge portion 22. For example, a width of the third bridge portion 23 may be identical to a width of the first bridge portion 12 and a width of the second bridge portion 22.

FIG. 4C is a plan view of an enlarged image of the portion IV shown in FIG. 3 as a portion of the stretchable display apparatus 1 according to an embodiment.

Referring to FIG. 4C, the stretchable display apparatus 1 may include the first island portions 11 spaced apart from one another in the first direction (e.g., the x direction or the −x direction) and the second direction (e.g., the y direction and the −y direction) and the first bridge portions 12 connecting the first island portions 11 adjacent to each other.

The first bridge portions 12 may be arranged spaced apart from each other by the first opening CS1 disposed between the first bridge portions 12. The first bridge portion 12 may have a serpentine shape. For example, as shown in FIG. 4C, the first bridge portion 12 may have a shape approximately like the letter “S”.

Each of the first island portions 11 may be connected to the plurality of first bridge portions 12. For example, each of the first island portions 11 may be connected to four first bridge portions 12. Two of the first bridge portions 12 may be arranged at two sides of the first island portion 11 in the first direction (e.g., the x direction or the −x direction), and another two of the first bridge portions 12 may be arranged at two sides of the first island portion in the second direction (e.g., the y direction or the −y direction). Four first bridge portions 12 may be respectively connected to four sides of the first island portion 11. Each of the four first bridge portions 12 may each be connected to an area disposed adjacent to each corner of the first island portion 11.

In the non-display area NDA, e.g., the first non-display area NDA1 shown in FIG. 4C, the stretchable display apparatus 1 may include the second island portions 21 spaced apart from one another in the first direction (e.g., the x direction or the −x direction) and the second direction (e.g., the y direction or the −y direction) and the second bridge portions 22 connecting the second island portions 21 disposed adjacent to each other.

The second bridge portions 22 may be arranged spaced apart from each other by the second opening CS2 disposed between the second bridge portions 22. The second bridge portion 22 may have a serpentine shape. For example, as shown in FIG. 4C, the second bridge portion 22 may have a shape approximately like the letter “S”. A size and/or a width of the second bridge portion 22 may be different from a size and/or a width of the first bridge portion 12. For example, the size and/or the width of the second bridge portion 22 may be greater than the size and/or the width of the first bridge portion 12. A radius of curvature of a rounded portion of the second bridge portion 22 may be different from a radius of curvature of a rounded portion of the first bridge portion 12. For example, the radius of curvature of the rounded portion of the second bridge portion 22 may be greater than the radius of curvature of the rounded portion of the first bridge portion 12.

Each of the second island portions 21 may be connected to a plurality of second bridge portions 22. Each of the second island portions 21 may be connected to four second bridge portions 22. Two of the second bridge portions 22 may be arranged at two sides of the second island portion 21 in the first direction (e.g., the x direction or the −x direction), and another two of the second bridge portions 22 may be arranged at two sides of the second island portion 21 in the second direction (e.g., the y direction or the −y direction). In an embodiment, four second bridge portions 22 may be respectively connected to four sides of the second island portion 21. Each of the second bridge portions 22 may be connected to a center portion of each side of the second island portion 21.

A length of the second island portions 21 of any one row arranged in the first non-display area NDA1 may have a length corresponding to the first island portions 11 in the plurality of rows arranged in the display area DA. For example, the second island portions 21 in any one row arranged in the first non-display area NDA1 may have a length corresponding to the first island portions 11 arranged in the (i)^{th} row and the first island portions 11 arranged in the (i+1)^{th} row in the display area DA (where i is a positive number). In another embodiment, the length of the second island portions 21 in any one row may have a length corresponding to the first island portions 11 in n rows (where n is a positive number of three or greater).

The non-display area NDA, e.g., the first non-display area NDA1, may include the first sub-non-display area SNDA1 in which the second island portions 21 and the second bridge portions 22 are arranged and the second sub-non-display area SNDA2 disposed between the first sub-non-display area SNDA1 and the display area DA. Third bridge portions 23 connecting the display area DA and the first sub-non-display area SNDA1 may be arranged in the second sub-non-display area SNDA2. An end portion of the third bridge portion 23 may be connected to the second island portion 21, and another end portion of the third bridge portion 23 may be connected to the first island portion 11. For example, the one end portion of the third bridge portion 23 may be connected to a center portion of a side of the second island portion 21, and the other end portion of the third bridge portion 23 may be connected to a center portion of a side of the first island portion 11.

The third bridge portion 23 may have a serpentine shape. For example, the shape of the third bridge portion 23 may be different from the shapes of the first bridge portion 12 and the second bridge portion 22. The width of the third bridge portion 23 may be different from the width of the first bridge portion 12 and the width of the second bridge portion 22. The width of the third bridge portion 23 may be greater than the width of the first bridge portion 12 and less than the width of the second bridge portion 22. Third openings CS3 and fourth openings CS4 having different shapes may be alternately arranged between the third bridge portions 23 in the second direction (e.g., the y direction or the −y direction).

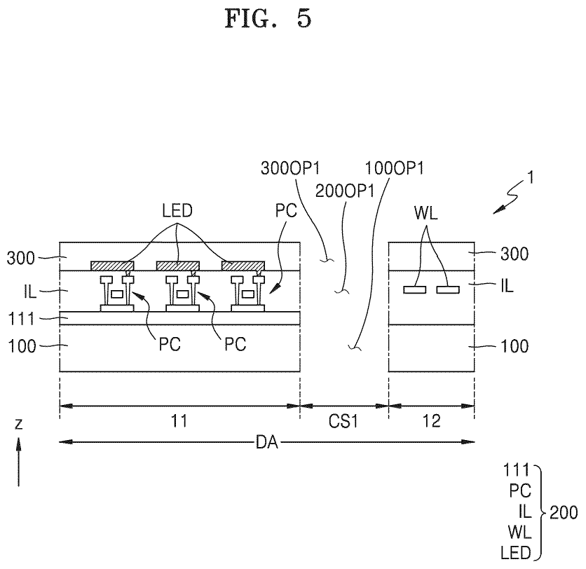

FIG. 5 is a cross-sectional view schematically illustrating the first island portion 11 and the first bridge portion 12 arranged in the display area DA of the stretchable display apparatus 1 according to an embodiment.

Referring to FIG. 5, the first island portion 11 and the first bridge portion 12 arranged in the display area DA may be arranged spaced apart from each other with the first opening CS1 disposed therebetween. The first island portion 11 may include emission elements LED and a circuit configured to drive the emission elements LED and electrically connected to the emission elements LED, e.g., the pixel driving circuit unit PC, and the first bridge portion 12 may include wirings WL electrically connected to the pixel driving circuit units PC respectively arranged in the first island portions 11 disposed adjacent to each other.

In the first island portion 11, a buffer layer 111 including an inorganic insulating material may be disposed on the substrate 100, and the pixel driving circuit unit PC may be disposed on the buffer layer 111. An insulating layer IL including an inorganic insulating material and/or an organic insulating material IL may be disposed between the pixel driving circuit unit PC and the emission elements LED. The emission elements LED may be disposed on the insulating layer IL, and may be electrically connected to a corresponding pixel driving circuit unit PC. The emission elements LED may emit light having different colors or a same color. In an embodiment, the emission elements LED may be configured to emit red, green, and blue light, respectively. In some embodiments, the emission elements LED may be configured to emit white light. In another embodiment, the emission elements LED may be configured to emit red, green, blue, or white light, respectively.

The substrate 100 may include a polymer resin such as polyethersulfone, polyarylate, polyetherimide, polyethylene naphthalate, polyethylene terephthalate, polyphenylene sulfide, polyimide, polycarbonate, cellulose triacetate, and cellulose acetate propionate. In an embodiment, the substrate 100 may include a single layer including the aforementioned polymer resin. In another embodiment, the substrate 100 may have a multi-layer structure including a base layer including the aforementioned polymer resin and a barrier layer including an inorganic insulating material. The substrate 100 including the polymer resin may be flexible, rollable, and bendable.

In an embodiment, FIG. 5 illustrates that three pixel driving circuit units PC are disposed in each of the first island portions 11 and three emission elements LED are connected to each of the pixel driving circuit units PC, the disclosure not limited thereto. In another embodiment, the numbers of the pixel driving circuit units PC and the emission elements LED arranged in the first island portion may be one, two, or at least four.

An encapsulation layer 300 may be disposed on the emission elements LED and may protect the emission elements LED from an external force and/or moisture. The encapsulation layer 300 may include an inorganic encapsulation layer and/or an organic encapsulation layer. In some embodiments, the encapsulation layer 300 may include a structure in which an inorganic encapsulation layer including an inorganic insulating material, an organic encapsulation layer including an organic insulating material, and an inorganic encapsulation layer including an inorganic insulating material are stacked. In another embodiment, the encapsulation layer 300 may include an organic material such as a resin. In some embodiments, the encapsulation layer 300 may include urethane epoxy acrylate. The encapsulation layer 300 may include a photosensitive material, e.g., a material such as a photoresist.

In the first bridge portion 12, an insulating layer IL including an organic insulating material may be disposed on the substrate 100. When the stretchable display apparatus 1 extends, unlike the first island portion 11, the first bridge portion 12 that is deformed to a relatively greater degree may not include a layer including an inorganic insulating material in which cracks easily occur.

In an embodiment, the substrate 100 corresponding to the first bridge portion 12 may have a stack structure identical to a stack structure of the substrate 100 corresponding to the first island portion 11. In an embodiment, the substrate 100 corresponding to the first bridge portion 12 and the substrate 100 corresponding to the first island portion 11 may indicate a polymer resin layer formed together in a same process. In another embodiment, the substrate 100 corresponding to the first bridge portion 12 may have a stack structure different from the stack structure of the substrate 100 corresponding to the first island portion 11. In some embodiments, the substrate 100 corresponding to the first island portion 11 may have a multi-layered structure including a base layer including a polymer resin and a barrier layer including an inorganic insulating material, and the substrate 100 corresponding to the first bridge portion 12 may have a structure of a polymer resin layer without a layer including an inorganic insulating material.

As described above, the wirings WL of the first bridge portion 12 may include the signal lines (e.g., the gate line, the data line, and the like) configured to provide electrical signals or the voltage lines (e.g., the driving voltage line, the initialization voltage line, and the like) configured to provide voltages to the transistor included in the pixel driving circuit unit PC of the first island portion 11. The encapsulation layer 300 may also be arranged in the first bridge portion 12. In another embodiment, the encapsulation layer 300 may not be disposed in the first bridge portion 12.

Referring to FIGS. 4A to 4C and FIG. 5, the substrate 100 corresponding to the first island portion 11 and the substrate 100 corresponding to the first bridge portion 12 may be connected to each other. In other words, the plan views shown above in FIGS. 4A to 4C may be substantially identical to the plan view of the substrate 100 shown in FIG. 5. In other words, the substrate 100 may include an area corresponding to the first island portion 11, an area corresponding to the first bridge portion 12, and an opening 100OP1 having a shape identical to a shape of a first opening CS1.

Similarly, the encapsulation layer 300 corresponding to the first island portion 11 and the encapsulation layer 300 corresponding to the first bridge portion 12 may be connected to each other. For example, the plan views shown above in FIGS. 4A to 4C may be substantially identical to the top plan view of the encapsulation layer 300. In other words, the encapsulation layer 300 may include an area corresponding to the first island portion 11, an area corresponding to the first bridge portion 12, and an opening 300OP having a shape identical to a shape of the first opening CS1.

A circuit-emission element layer 200 disposed between the substrate 100 and the encapsulation layer 300 may include a buffer layer 111, a pixel driving circuit unit PC, the wirings WL, an insulating layer IL and an emission element LED. Like the substrate 100, the plan views shown above in FIGS. 4A to 4C may be substantially identical to a plan view of the circuit-emission element layer 200. In other words, the circuit-emission element layer 200 may include an opening 200OP1 having a shape identical to the shape of the first opening CS1.

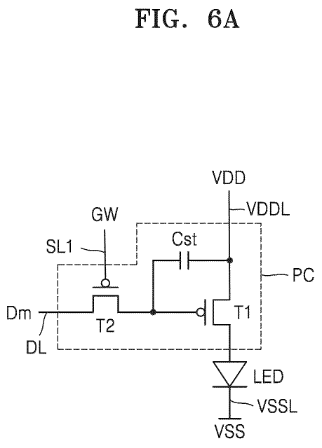

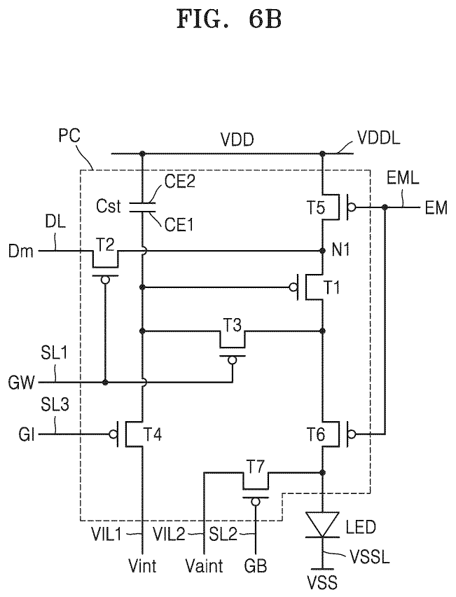

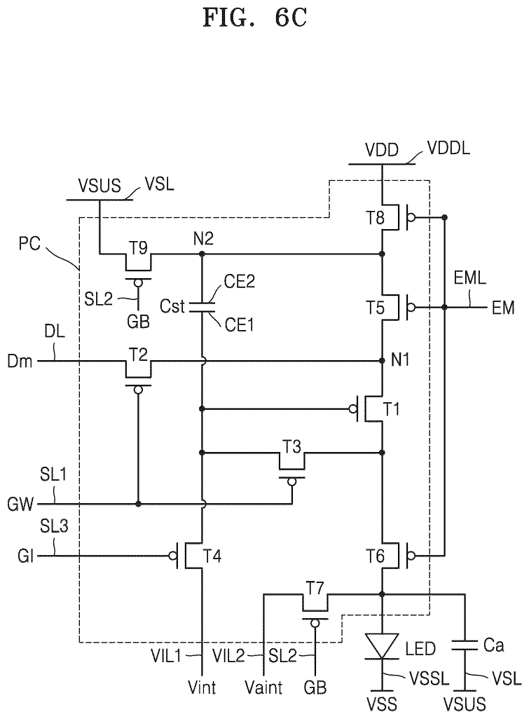

FIGS. 6A to 6C are equivalent circuit diagrams of subpixels of the stretchable display apparatus 1 according to an embodiment.

Referring to FIG. 6A, the emission element LED corresponding to the subpixel is electrically connected to the pixel driving circuit unit PC, and the pixel driving circuit unit PC may include a first transistor T1, a second transistor T2, and a storage capacitor Cst. The pixel driving circuit unit PC may be electrically connected to signal lines and voltage lines. The signal lines may include a gate line, e.g., a first scan line SL1, and a data line DL, and the voltage lines may include a first voltage line VDDL and a second voltage line VSSL.

The second transistor T2 may be electrically connected to the first scan line SL1 and the data line DL. The first scan line SL1 may supply a first scan signal GW to a gate electrode of the second transistor T2. The second transistor T2 may be configured to deliver a data signal Dm input from the data line DL to the first transistor T1 in response to the first scan signal GW input from the first scan line SL1.

The storage capacitor Cst may be electrically connected between the second transistor T2 and the first voltage line VDDL, and may be configured to store a voltage corresponding to a difference between a voltage delivered from the second transistor T2 and a first power voltage VDD provided from the first voltage line VDDL.

The first transistor T1, which is a driving transistor, may be configured to control a driving current flowing through the emission element LED. The first transistor T1 may be connected between the first voltage line VDDL and the emission element LED. The first transistor T1 may be configured to control a driving current flowing from the first voltage line VDDL through the emission element LED according to a value of the voltage stored in the storage capacitor Cst. The emission element LED be configured to emit may light of certain luminance in response to the driving current. A first electrode of the emission element LED may be electrically connected to the first transistor T1, and a second electrode of the emission element LED may be electrically connected to a second voltage line VSSL configured to provide a second power voltage VSS.

Although FIG. 6A illustrates that the pixel driving circuit unit PC includes two transistors and one storage capacitor, in another embodiment, the pixel driving circuit unit PC may include three or more transistors.

Referring to FIG. 6B, the pixel driving circuit unit PC may include a first transistor T1, a second transistor T2, a third transistor T3, a fourth transistor T4, a fifth transistor T5, a sixth transistor T6, a seventh transistor T7, and a storage capacitor Cst.

The pixel driving circuit unit PC may be electrically connected to signal lines and voltage lines. The signal lines may include gate lines, e.g., a first scan line SL1, a second scan line SL2, a third scan line SL3, and an emission control line EML, and a data line DL. The voltage lines may include a first initialization line VIL1, a second initialization line VIL2, a first voltage line VDDL and a second voltage line VSSL.

The first voltage line VDDL may be configured to supply the first power voltage VDD to the first transistor T1. The first initialization line VIL1 may be configured to supply a first initialization voltage Vint, which initializes the first transistor T1, to the pixel driving circuit unit PC. The second initialization voltage line VIL2 may be configured to supply a second initialization voltage Vaint, which initializes the first electrode of the emission element LED, to the pixel driving circuit unit PC.

The first transistor T1 may be electrically connected to the first voltage line VDDL via the fifth transistor T5, and may be electrically connected to the emission element LED via the sixth transistor T6. The first transistor T1 is configured to function as the driving transistor, receive the data signal Dm in response to a switching operation of the second transistor T2, and provide the driving current to the emission element LED.

The second transistor T2, which is a data write transistor, is electrically connected to the first scan line SL1 and the data line DL. The second transistor T2 is electrically connected to the first voltage line VDDL via the fifth transistor T5. The second transistor T2 is turned on in response to the first scan signal GW delivered through the first scan line SL1 and performs a switching operation of delivering the data signal Dm, which is supplied from the data line DL, to a first node N1.

The third transistor T3 is electrically connected to the first scan line SL1 and is also electrically connected to the emission element LED via the sixth transistor T6. The third transistor T3 may be turned on in response to the first scan signal GW delivered through the first scan signal SL1 and may diode-connect the first transistor T1.

The fourth transistor T4, which is a first initialization transistor, is electrically connected to a third scan line SL3 and the first initialization voltage line VIL1. The fourth transistor T4 is turned on in response to a third scan signal GI delivered through the third scan line SL3, delivers the first initialization voltage Vint from the first initialization voltage VIL1 to the gate electrode of the first transistor T1, and initializes a voltage of the gate electrode of the first transistor T1. The third scan signal GI may correspond to a first scan signal of another pixel driving circuit unit PC arranged in a previous row before a row including a corresponding pixel driving circuit unit PC.

The fifth transistor T5 may be an operation control transistor, and the sixth transistor T6 may be an emission control transistor. The fifth transistor T5 and the sixth transistor T6 are electrically connected to the emission control line EML, and are simultaneously turned on in response to an emission control signal EM delivered through the emission control line EML, and form a current path such that the driving current may flow in a direction from the first voltage line VDDL toward the emission element LED.

The seventh transistor T7, which is a second initialization transistor, may be electrically connected to the second scan line SL2, the second initialization voltage line VIL2, and the sixth transistor T6. The seventh transistor T7 may be turned on in response to a second scan signal GB received through the second scan line SL2, and may initialize a first electrode of the emission element LED by delivering the second initialization voltage Vaint from the second initialization voltage line VIL2 to the first electrode of the emission element LED.

The storage capacitor Cst may include the first electrode CE1 and the second electrode CE2. The first electrode CE1 may be electrically connected to the gate electrode of the first transistor T1, and the second electrode CE2 may be electrically connected to the first voltage line VDDL. The storage capacitor Cst may be configured to maintain a voltage applied to the gate electrode of the first transistor T1 by storing and maintaining a voltage difference between the gate electrodes of the first transistor T1 and the first voltage line VDDL.

Referring to FIG. 6C, the pixel driving circuit unit PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca.

The pixel driving circuit unit PC may be electrically connected to signal lines and voltage lines. The signal lines may include gate lines, e.g., a first scan line SL1, a second scan line SL2, a third scan line SL3, and an emission control line EML, and a data line DL. The voltage lines may include a first initialization voltage line VIL1, a second initialization voltage line VIL2, a sustain voltage line VSL, a first voltage line VDDL, and a second voltage line VSSL.

The first voltage line VDDL may be configured to deliver the first power voltage VDD to the first transistor T1. The first initialization line VILI may be configured to deliver a first initialization voltage Vint, which initializes the first transistor T1, to the pixel driving circuit unit PC. The second initialization voltage line VIL2 may be configured to deliver a second initialization voltage Vaint, which initializes the first electrode of the emission element LED, to the pixel driving circuit unit PC. The sustain voltage line VSL may be configured to provide a sustain voltage VSUS to a second node N2, e.g., the second electrode CE2 of the storage capacitor Cst in an initialization section and a data write section.

The first transistor T1 may be electrically connected to the first voltage line VDDL via the fifth transistor T5 and the eighth transistor T8, and may be electrically connected to the emission element LED via the sixth transistor T6. The first transistor T1 may be configured to function as the driving transistor, receive the data signal Dm in response to a switching operation of the second transistor T2, and provide the driving current to the emission element LED.

The second transistor T2 is electrically connected to the first scan line SLI and the data line DL, and is also electrically connected to the first voltage line VDDL via the fifth transistor T5 and the eighth transistor T8. The second transistor T2 is turned on in response to the first scan signal GW delivered from the first scan line SL1 and performs a switching operation of delivering the data signal Dm, which is delivered from the data line DL, to the first node N1.

The third transistor T3 is electrically connected to the first scan line SL1 and is also electrically connected to the emission element LED via the sixth transistor T6. The third transistor T3 may be configured to compensate for a threshold voltage of the first transistor T1 by being turned on in response to the first scan signal GW, which is delivered through the first scan signal SL1, and diode-connect the first transistor T1.

The fourth transistor T4 is electrically connected to the third scan line SL3 and the first initialization voltage line VIL1, is turned on in response in the third scan signal GI delivered through the third scan line SL3 and delivers the first initialization voltage Vint from the first initialization voltage line VIL1 to a gate electrode of the first transistor T1, to thereby initialize a voltage of the gate electrode of the first transistor T1. The third scan signal GI may correspond to a first scan signal of another pixel driving circuit unit PC arranged in a previous row before a row including a corresponding pixel driving circuit unit PC.

The fifth transistor T5, the sixth transistor T6, and the eighth transistor T8 are electrically connected to the emission control line EML, are simultaneously turned on in response to the emission control signal EM delivered through the emission control line EML, and form a current path such that the driving current may flow from the first voltage line VDDL toward the emission element LED.

The seventh transistor T7, which is a second initialization transistor, may be electrically connected to the second scan line SL2, the second initialization voltage line VIL2, and the first (anode) electrode of the emission element LED and the sixth transistor T6. The seventh transistor T7 is turned on in response to the second scan signal GB delivered through the second scan line SL2, delivers the second initialization voltage Vaint from the second initialization line VIL2 to the first electrode of the emission element LED, and initializes the first electrode of the emission element LED.

The ninth transistor T9 may be electrically connected to the second scan line SL2, the second electrode CE2 of the storage capacitor Cst, and the sustain voltage line VSL. The ninth transistor T9 may be turned on in response to the second scan signal GB delivered through the second scan line SL2, and may be configured to deliver the sustain voltage VSUS to the second node N2, e.g., the second electrode CE2 of the storage capacitor Cst, in the initialization section and the data write section.

The eighth transistor T8 and the ninth transistor T9 may each be electrically connected to the second node N2, e.g., the second electrode CE2 of the storage capacitor Cst. In some embodiments, in the initialization section and the data write section, the eighth transistor T8 may be turned off and the ninth transistor T9 may be turned on, and, in an emission section, the eighth transistor T8 may be turned on and the ninth transistor T9 may be turned off. In the initialization section and the data write section, the second node N2, to which the sustain voltage VSUS is delivered, may be configured to improve long range uniformity (LRU) of the stretchable display apparatus 1 according to a voltage drop of the first voltage line VDDL.

The storage capacitor Cst may include the first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the sustain voltage line VSL, and the first electrode of the emission element LED. The auxiliary capacitor Ca may be configured to store and maintain a voltage corresponding to a difference between voltages of the first electrode of the emission element LED and the sustain voltage line VSL while the seventh transistor T7 and the ninth transistor T9 are turned on, to thereby prevent increase in black luminance when the sixth transistor T6 is off.

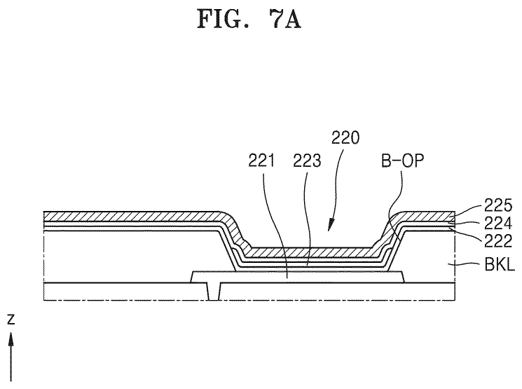

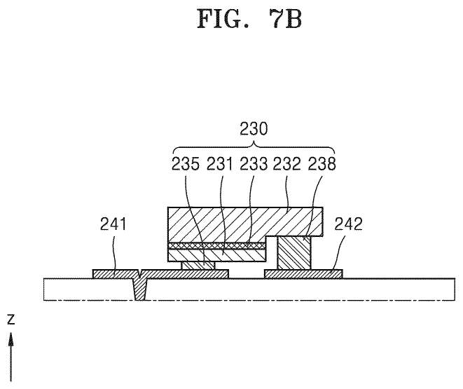

FIG. 7A is a cross-sectional view schematically illustrating an emission element of the stretchable display apparatus according to an embodiment.

Referring to FIG. 7A, the emission element according to an embodiment may include an organic emission diode 220 including an organic material. The organic emission diode 220 may include a first electrode 221 disposed on an insulating layer, a second electrode 225 facing the first electrode 221, and an emission layer 223 disposed between the first electrode 221 and the second electrode 225. A first function layer 222 may be disposed between the first electrode 221 and the emission layer 223, and a second function layer 224 may be disposed between the emission layer 223 and the second electrode 225.

An edge of the first electrode 221 may be covered with a bank layer BKL including an insulating material. The bank layer BKL may include an opening B-OP overlapping a center portion of the first electrode 221.

The first electrode may include a conductive oxide such as indium oxide (ITO), indium zinc oxide (IZO), zinc oxide (ZnO), indium oxide (In₂O₃), indium gallium oxide (IGO), or aluminum zinc oxide (AZO). In another embodiment, the first electrode 221 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or compounds thereof. In another embodiment, the first electrode 221 may further include a layer including ITO, IZO, ZnO, AZO, or In₂O₃ under/over the aforementioned reflective layer.

The emission layer 223 may include a high-molecular or low-molecular organic material emitting light of certain colors. The first function layer 222 may include a hole transport layer (HTL) and/or a hole injection layer (HIL). The second function layer 224 may include an electron transport layer (ETL) and/or an electron injection layer (EIL).

The second electrode 225 may include a conductive material having a small work function. For example, the second electrode 225 may include a (semi) transparent layer including Ag, Mg, Al, Pt, Pd, Au, Ni, Nd, Ir, Cr, Li, Ca, or alloys thereof. Alternatively, the second electrode 225 may further include including ITO, IZO, ZnO, AZO, or In₂O₃ on the (semi) transparent layer including the aforementioned materials.

FIG. 7B is a cross-sectional view schematically illustrating an emission element of the stretchable display apparatus 1 according to an embodiment.

Referring to FIG. 7B, the emission element according to an embodiment may include an inorganic emission diode 230 including an inorganic material. The inorganic emission diode 230 may include a first semiconductor layer 231, a second semiconductor layer 232, an intermediate layer 233 disposed between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic emission diode 230 may be respectively electrically connected to a first electrode pad 241 and a second electrode pad 242 disposed on a same layer.

In some embodiments, the first semiconductor layer 231 may include a p-type semiconductor layer. The p-type semiconductor layer may be selected from among semiconductor materials having a composition formula of InₓAl_{y}Ga_{1-x-y}N (0≤x≤1, 0≤y≤1, 0≤x+y≤1), e.g., GaN, AlN, AlGaN, InGaN, InN, InAlGaN, AlInN, and may be doped with a p-type dopant such as Mg, Zn, Ca, Sr, Ba, and the like.

The second semiconductor layer 232 may include, for example, a n-type semiconductor layer. The n-type semiconductor layer may be selected from among semiconductor materials having a composition formula of InₓAl_{y}Ga_{1-x-y}N (0≤x≤1, 0≤y≤1, 0≤x+y≤1), e.g., GaN, AlN, AlGaN, InGaN, InN, InAlGaN, AlInN, and may be doped with a n-type dopant such as Si, Ge, Sn, and the like.

An intermediate layer 233, which is an area in which electrons and holes are recombined, transitions to a lower energy level as the electrons and holes are recombined, and may generate light having a corresponding wavelength. The intermediate layer 233 may be formed to include a semiconductor material having a composition formula such as InₓAl_{y}Ga_{1-x-y}N (0≤x≤1, 0≤y≤1, 0≤x+y≤1), and may be formed into a single quantum well structure or multi quantum well (MQW) structure. In addition, the intermediate layer 233 may include a quantum wire structure or a quantum dot structure.

Although FIG. 7B illustrates that the first semiconductor layer 231 includes a p-type semiconductor layer and the second semiconductor layer 232 includes an n-type semiconductor layer, the disclosure is not limited thereto. In another embodiment, the first semiconductor layer 231 may include a n-type semiconductor layer and the second semiconductor layer 232 may include a p-type semiconductor layer.

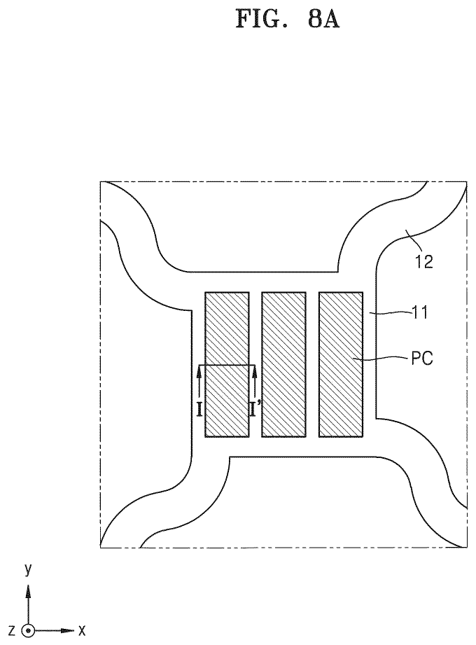

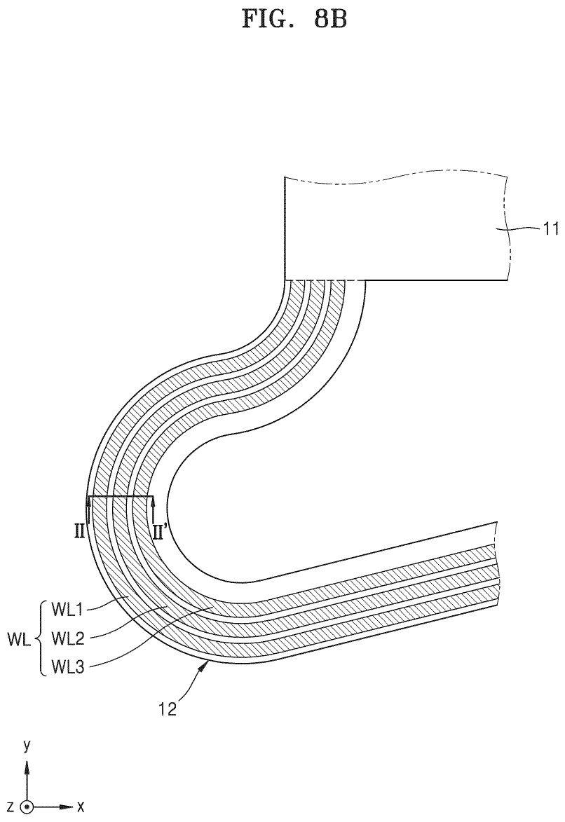

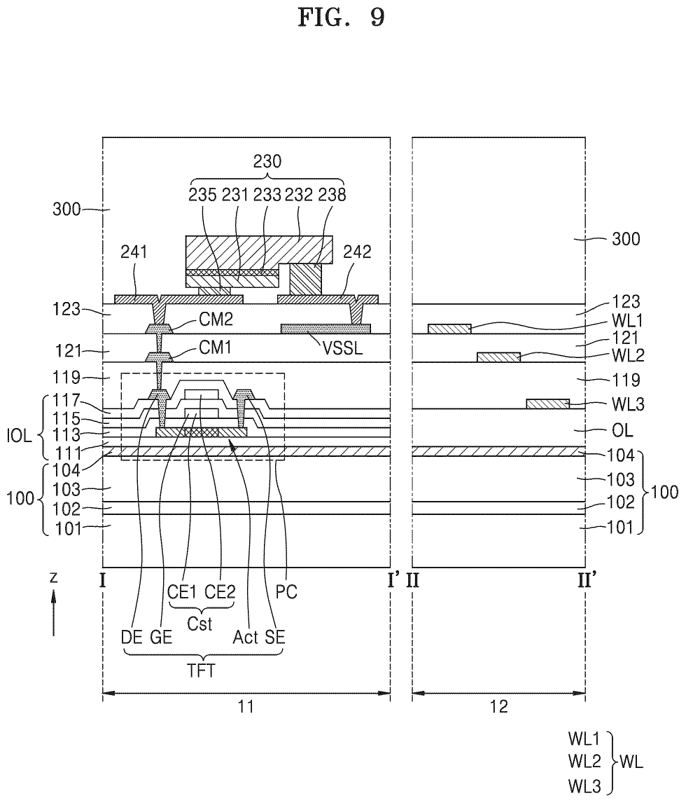

FIG. 8A is a plan view illustrating an enlarged image of the first island portion 11 of the stretchable display apparatus according to an embodiment, and FIG. 8B is a plan view illustrating an arrangement of the wirings WL on the first bridge portion 12 of the stretchable display apparatus 1 according to an embodiment. In addition, FIG. 9 illustrates a cross-section taken along a line I-I′ shown in FIG. 8A and a cross-section taken along a line II-II′ shown in FIG. 8B.

Referring to FIGS. 8A, 8B and 9, the first island portion 11 arranged in the display area DA may include emission elements and the pixel driving circuit unit PC electrically connected to the emission elements. As described above, the pixel driving circuit unit PC may include a plurality of transistors and at least one capacitor. Although FIG. 8A illustrates that three pixel driving circuit units PC are arranged in the first island portion 11, the embodiments are not limited thereto. In other embodiments, the numbers of the pixel driving circuit units PC and the emission elements arranged in the first island portion 11 may be one, two, or four or more.

Referring to FIG. 9, the substrate 100 corresponding to the first island portion 11 may include a first base layer 101, a first barrier layer 102, a second base layer 103, and a second barrier layer 104. The first base layer 101 and the second base layer 103 may each include a polymer resin, e.g., polyethersulfone, polyarylate, polyetherimide, polyethylene naphthalate, polyethylene terephthalate, polyphenylene sulfide, polyimide, polycarbonate, cellulose triacetate, and cellulose acetate propionate. The first barrier layer 102 and the second barrier layer 104 may each include an inorganic insulating material such as silicon oxide, silicon nitride, and silicon oxynitride.

The buffer layer 111 may be disposed on the substrate 100, and the pixel driving circuit unit PC may be disposed on the buffer layer 111. The buffer layer 111 may include an inorganic insulating material such as silicon oxide, silicon nitride, and silicon oxynitride.

A thin-film transistor TFT may include a semiconductor layer Act, a gate electrode GE, a source electrode SE, and a drain electrode DE. Although FIG. 9 illustrates a top-gate type thin-film transistor in which the gate electrode GE is disposed on the semiconductor layer Act with a gate insulating layer 113 interposed therebetween, according to another embodiment, the thin-film transistor TFT may include a bottom-gate type thin-film transistor.

The semiconductor layer Act may include polysilicon. Alternatively, the semiconductor layer Act may include amorphous silicon, an oxide semiconductor, an organic semiconductor, and the like. The gate electrode GE may include a low-resistance metal material. The gate electrode GE may include a conductive material including molybdenum (Mo), aluminum (Al), copper (Cu), titanium (Ti), and the like, and may include multiple layers or a single layer including the aforementioned materials.

The gate insulating layer 113 disposed between the semiconductor layer Act and the gate electrode GE may include an inorganic insulating material such as silicon oxide, silicon nitride, silicon oxynitride, aluminum oxide, and titanium oxide. The gate insulating layer 113 may include multiple layers or a single layer including the aforementioned materials.

The source electrode SE and the drain electrode DE may be disposed on a same layer, e.g., a second interlayer insulating layer 117, and may include a same material. The source electrode SE and the drain electrode DE may each include a conductive material, and may each include multiple layers or a single layer. The second interlayer insulating layer 117 may include an inorganic insulating material such as silicon oxide, silicon nitride, silicon oxynitride, aluminum oxide, titanium oxide, and may include a single layer or multiple layers including the aforementioned materials.

The storage capacitor Cst may include the first electrode CE1 and the second electrode CE2 overlapping each other with a first interlayer insulating layer 115 interposed therebetween. The storage capacitor Cst may overlap the thin-film transistor TFT. Regarding this, FIG. 9 illustrates that the gate electrode GE of the thin-film transistor TFT is the first electrode CE1 of the storage capacitor Cst. In another embodiment, the storage capacitor Cst may not overlap the thin-film transistor TFT. The storage capacitor Cst may be covered with a second interlayer insulating layer 117. The second electrode CE2 of the storage capacitor Cst may include a conductive material, and may include multiple layers or a single layer. The first interlayer insulating layer 115 may be disposed between the gate insulating layer 113 and the second interlayer insulating layer 117. The first interlayer insulating layer 115 may include an inorganic insulating material such as silicon oxide, silicon nitride, silicon oxynitride, aluminum oxide, and titanium oxide, and may include a single layer or multiple layers including the aforementioned materials.

An inorganic insulating material layer IOL on the substrate 100 may include, for example, the buffer layer 111, the gate insulating layer 113, the first interlayer insulating layer 115, and the second interlayer insulating layer 117.

A first organic insulating layer 119 may be disposed on the second interlayer insulating layer 117 on the source electrode SE and the drain electrode DE, and a second organic insulating layer 121 may be disposed on the first organic insulating layer 119. The first organic insulating layer 119 and the second organic insulating layer 121 may each include an organic insulating material such as polyimide.

A second voltage line VSSL may be disposed on the second organic insulating layer 121, and a third organic insulating layer 123 may be disposed on the second organic insulating layer 121 on the second voltage line VSSL. The third organic insulating layer 123 may include an organic insulating material such as polyimide. The second voltage line VSSL may include a conductive material, and may include multiple layers or a single layer.

The first electrode pad 241 and the second electrode pad 242 may be disposed on the third organic insulating layer 123. The first electrode pad 241 may be electrically connected to the thin-film transistor TFT through a first connection electrode CM1 disposed between the first organic insulating layer 119 and the second organic insulating layer 121 and a second connection electrode CM2 disposed between the second organic insulating layer 121 and the third organic insulating layer 123. The inorganic emission diode 230 on the first electrode pad 241 and the second electrode pad 242 is as described above with reference to FIG. 7B. An emission diode, e.g., the inorganic emission diode 230 may be protected by the encapsulation layer 300, and the encapsulation layer 300 may include an inorganic encapsulation layer and/or an organic encapsulation layer, or may include an organic material such as a resin. Although FIG. 9 illustrates that the emission diode is the inorganic emission diode 230 described with reference to FIG. 7B, in another embodiment, the emission diode may include the organic emission diode 220 described above with reference to FIG. 7A.

Referring to FIG. 8B, the first bridge portion 12 may include a plurality of wirings WL electrically connected to the pixel driving circuit units PC respectively arranged in the island portions 11 disposed adjacent to one another. As described above, the wirings WL may include signal lines (e.g., the gate line, the data line) or voltage lines (e.g., the driving voltage line, the initialization voltage line) configured to provide electrical signals to the transistors included in the pixel driving circuit units PC of the first island portion 11. Although FIG. 8B illustrates that the plurality of wirings WL, e.g., a first wiring WL1, a second wiring WL2, and a third wiring WL3 are disposed on the first bridge portion 12, the embodiments are not limited thereto. In another embodiments, only one wiring WL may be disposed on the first bridge portion 12.

Referring to FIG. 9, according to an embodiment, the substrate 100 corresponding to the first bridge portion 12 may have a stack structure identical to a stack structure of the substrate 100 corresponding to the first island portion 11. In an embodiment, the substrate 100 corresponding to the first bridge portion 12 may include the first base layer 101, the first barrier layer 102, the second base layer 103, and the second barrier layer 104. In another embodiment, the substrate 100 corresponding to the first bridge portion 12 may have a stack structure different from the stack structure of the substrate 100 corresponding to the first island portion 11. The substrate 100 corresponding to the first bridge portion 12 may have a structure including the first base layer 101 and the second base layer 103.

The inorganic insulating material layer IOL may not be disposed on the substrate 100 in the first bridge portion 12, and an insulating layer OL, the first organic insulating layer 119, and the second organic insulating layer 121 may be disposed on the substrate 100 in the first bridge portion 12. The insulating layer OL may include an organic insulating material such as polyimide. In an embodiment, the insulating layer OL may have a thickness corresponding to a thickness of the inorganic insulating material layer IOL in the first island portion 11. In some embodiments, the insulating layer OL may also be omitted.

The plurality of wirings WL, e.g., the first wiring WL1, the second wiring WL2, and the third wiring WL3 may be respectively disposed on different layers but may be electrically connected to a same pixel driving circuit unit PC. For example, the first wiring WL1 may be disposed between the second organic insulating layer 121 and the third organic insulating layer 123, the second wiring WL2 may be disposed between the first organic insulating layer 119 and the second organic insulating layer 121, and the third wiring WL3 may be disposed between the insulating layer OL and the first organic insulating layer 119. However, the disclosure is not limited thereto, and in other embodiments, at least some of the first wiring WL1, the second wiring WL2, and the third wiring WL3 may be disposed on a same layer.

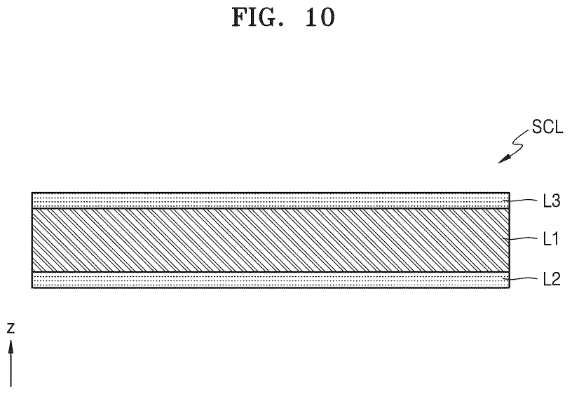

FIG. 10 shows a cross-sectional view of wirings or electrodes of the stretchable display apparatus which includes alloy layer according to an embodiment.

Referring to FIG. 10, a conductive layer SCL may include an alloy layer L1. In an embodiment, the alloy layer L1 may include a first layer. The alloy layer L1 may include an alloy of aluminum and a Rare-earth element. The alloy layer L1 may include an amorphous alloy layer. The amorphous alloy may not include a grain-boundary. The amorphous alloy may undergo elastic deformation without plastic deformation, and may have a high elastic limit. In the present specification, the amorphous alloy may include an alloy including amorphous phase only and an alloy including a nanocrystalline phase having a crystal size of only several nanometers dispersed in an amorphous phase.

An atomic radius of the rare-earth element may be greater than an atomic radius of aluminum by more than or equal to about 25% of the atomic radius of aluminum. When a difference in atomic radiuses between the rare-earth element and the Al is about 25% or greater, a crystal lattice of Al may be distorted. An electronegativity of the rare-earth element may be less than an electronegativity of aluminum. The electronegativity of the rare-earth element may be about 1.0 or greater but not more than about 1.2. In an embodiment, the rare-earth element may include at least one of yittrium (Y), samarium (Sm), cerium (Ce), and lanthanium (La). Such rare-earth elements may have excellent ability of forming an amorphous material.

In an embodiment, the alloy layer L1 may include a binary alloy having a composition formula of AlₐM_{b}. Here, M may include at least one rare-earth element selected from among Y, Sm, Ce, and La. “a” indicates an atomic % (at %) of Al atoms and “b” indicates an atomic % of the rare-earth element atoms included in the alloy layer L1, where the sum of “a” and “b” may be 100. In an embodiment, “a” may be at least about 90 but not more than about 96 or less, and “b” may be at least about 4 but not more than about 10. In other words, with reference to the total atomic weight of the alloy layer L1, the content of aluminum may be at least about 90 at % but not more than about 96 at %, and the content of the rare-earth element M may be least about 4 at % but not more than about 10 at %. When aluminum and the rare-earth element included in the alloy layer L1 satisfy the aforementioned range, the alloy layer L1 may include an amorphous alloy layer having an excellent electrical conductivity. When the content of aluminum is less than about 90 at %, the resistivity of the alloy layer L1 may increase. When the content of aluminum is greater than about 96 at %, the alloy layer L1 may not have an amorphous phase. When the content of the rare-earth element M is less than about 4 at %, the alloy layer L1 may not have an amorphous phase. When the content of the rare-earth element M is greater than about 10 at %, the resistivity of the alloy layer L1 may increase. In an embodiment, the alloy layer L1 may include an alloy having a composition formula of AlₐY_{b} (90≤a≤96, 4≤b≤10), where Y is yittrium.

In some embodiments, the alloy layer L1 may further include nickel and/or cobalt. Nickel and cobalt may be elements stabilizing the amorphous phase. In some embodiments, the alloy layer L1 may include a ternary alloy or a quaternary alloy. In some embodiments, the alloy layer L1 may include a quaternary alloy having a composition formula of AlₐM_{b}Ni_{c}Co_{d}. Here, M may include at least one rare-earth element selected from among Y, Sm, Ce, and La. “a”, “b”, “c”, “d” each indicate a content (at %) of each element with reference to the total atomic weight of the alloy layer L1, and a sum of “a”, “b”, “c”, and “d” may be 100. In some embodiments, “a” may be about 80 or greater but not more than about 90, “b” may be about 5 or greater but not more than about 10, “c” may be about 3 or greater but not more than about 8, and “d” may be about 1 or greater but not more than 3. In other words, with reference to the total atomic weight of the alloy layer L1, a content of aluminum may be about 80 at % or greater but not more than about 90 at %; a content of the rare-earth element M may be about 5 at % or greater but not more than about 10 at %; a content of nickel may be about 3 at % or greater but not more than about 8 at %; and a content of cobalt may be about 1 at % or greater but not more than about 3 at %. In an embodiment, the alloy layer L1 may include an alloy having a composition formula of Al₈₅Y₈Ni₅Co₂.

Hereinafter, the embodiments will be described under a premise that the alloy layer L1 includes a binary alloy including Al and the rare-earth element.

In an embodiment, the resistivity of the alloy layer L1 may be about 10 μΩ·cm or greater but less than about 50 μΩ·cm. The resistivity of the alloy layer L1 may be about 10 μΩ·cm or greater but less than about 45 μΩ·cm. The resistivity of the alloy layer L1 may be about 10 μΩ·cm or greater but less than about 30 μΩ·cm. The resistivity of the alloy layer L1 may be about 10 μΩ·cm or greater but less than about 25 μΩ·cm. A total resistance of the alloy layer L1 may be proportional to the resistivity of the alloy layer L1. However, the total resistivity of the alloy layer L1 may be different according to a thickness and a width of the alloy layer L1 as well as according to the resistivity of the alloy layer L1.

In an embodiment, an elastic limit of the alloy layer L1 may be at least about 2%. The elastic limit of the alloy layer L1 may be at least about 2% but not more than about 3%. The elastic limit of the alloy layer L1 may be at least about 2.1% but not more than about 2.8%.

In an embodiment, the conductive layer SCL may further include a lower layer L2 disposed under the alloy layer L1 and an upper layer L3 disposed over the alloy layer L1. The conductive layer SCL may have a structure in which the lower layer L2, the alloy layer L1, and the upper layer L3 are sequentially stacked. In an embodiment, the lower layer L2 may include a second layer, and the upper layer L3 may include a third layer. The lower layer L2 and the upper layer L3 may each include a conductive material including Mo, Cu, Ti, and the like. The lower layer L2 and the upper layer L3 may include materials different from the material of the alloy layer L1. The lower layer L2 and the upper layer L3 may include a same material. In an embodiment, the lower layer L2 and the upper layer L3 may include titanium (Ti).

The aforementioned structure of the conductive layer SCL may be applied to the wiring WL arranged in the first bridge portion 12. The wiring WL arranged in the first bridge portion 12 may include the alloy layer L1 including the alloy of aluminum and the rare-earth element. For example, the first wiring WL1, the second wiring WL2, and the third wiring WL3 shown in FIG. 9 may include the alloy layer L1 including the alloy of aluminum and the Rare-earth element.

In a comparative example, the wiring arranged in the first bridge portion may include a pure aluminum layer, not the alloy layer. In this case, as the pure aluminum layer has a low elastic limit of about 0.2% to about 0.5%, the wirings may be partially destroyed in an area where the degree of deformation is high. Accordingly, in the first bridge portion having a serpentine shape, a design of wiring area to arrange the wirings may be limited.

However, according to an embodiment, the wirings WL arranged in the first bridge portion 12 may include the alloy layer L1 including the alloy of aluminum and the Rare-earth alloy. The alloy layer L1 may have a high elastic limit, and may have a resistivity similar to a resistivity of the pure aluminum layer. In this case, as the alloy layer L1 may have a high elastic limit of about 2% or greater, limit on the design of wiring area in the first bridge portion 12 may be reduced. In addition, when a tensile strength is applied to the first bridge portion 12 and the first bridge portion 12 extends in various directions, the danger of destruction of the wiring WL may be reduced, and lifespan of the wirings WL may increase. The reliability of the stretchable display apparatus may be improved.

In an embodiment, the structure of the conductive layer SCL may also be applied to connection electrodes arranged in the first island portion 11. The connection electrodes may be disposed between the inorganic insulating material layer IOL and the emission element. The connection electrodes may be disposed between the gate electrode GE of the thin-film transistor TFT and the emission element, and may be electrically connected to the thin-film transistor TFT and/or the emission element. For example, the connection electrodes, for example, the source electrode SE and the drain electrode DE, may be disposed between the inorganic insulating material layer IOL and the first organic insulating layer 119. The connection electrodes CM1 may be disposed between the first organic insulating layer 119 and the second organic insulating layer 121. The connection electrodes CM2 and VSSL may be disposed between the second organic insulating layer 121 and the third organic insulating layer 123. As disclosed above, the connection electrodes may include the source electrode SE, the drain electrode DE, the first connection electrode CM1, the second connection electrode CM2, and the second voltage line VSSL which are shown in FIG. 9. The connection electrodes arranged in the first island portion 11 may include the alloy layer L1 including the alloy of aluminum and the rare-earth element. For example, the source electrode SE, the drain electrode DE1, the first connection electrode CM1, the second connection electrode CM2, and the second voltage line VSSL may each include the alloy layer L1 including the alloy of aluminum and the rare-earth element.

In other embodiments, the structure of the conductive layer SCL may be only applied to the wirings WL arranged in the first bridge portion 12 and not to the connection electrode arranged in the first island portion 11. The connection electrodes arranged in the first island portion 11 may not include the alloy layer L1 including the alloy of aluminum and the rare-earth element. The connection electrodes arranged in the first island portion 11 may include, for example, a conductive material including Mo, Al, Cu, Ti, and the like. In an embodiment, the source electrode SE, the drain electrode DE, the first connection electrode CM1, the second connection electrode CM2, and the second voltage line VSSL may each include a pure aluminum layer, not the alloy layer L1. For example, the source electrode SE, the drain electrode DE, the first connection electrode CM1, the second connection electrode CM2, and the second voltage line VSSL may each include a stack structure including a Ti layer/an Al layer/a Ti layer.

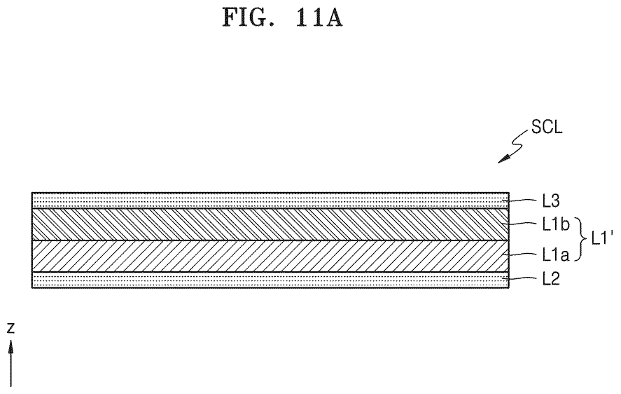

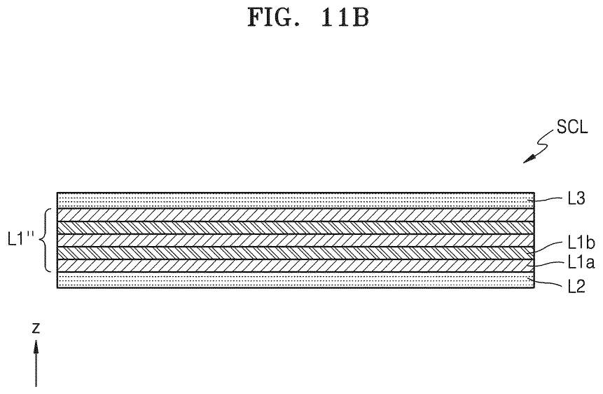

FIGS. 11A and 11B are cross-sectional views of wirings or connection electrodes including alloy layers of the stretchable display apparatus according to another embodiment. FIGS. 11A and 11B, which illustrate embodiments modified from the embodiment shown in FIG. 10, show differences from the aforementioned embodiments in terms of a structure of the alloy layer. Hereinafter, differences will be mainly described, and same descriptions will not be repeatedly given.

Referring to FIG. 11A, the conductive layer SCL may include an alloy layer L1′. The alloy layer L1′ may include a first sub layer L1a and a second sub layer L1b disposed on the first sub layer L1a. In an embodiment, the first sub layer L1a may include pure Al. The second sub layer L1b may include an alloy of Al and the Rare-earth element. A thickness of the first sub layer L1a may be less than a thickness of the alloy layer L1 shown in FIG. 10. A thickness of the second sub layer L1b may be less than a thickness of the alloy layer L1 shown in FIG. 10. In another embodiment, the first sub layer L1a and the second sub layer L1b may be stacked in an opposite order.

Although FIG. 11A illustrates that the alloy layer L1′ includes one first sub layer L1a and one second sub layer L1b, the embodiments are not limited thereto. Referring to FIG. 11B, in another embodiment, an alloy layer L1″ may have a structure in which a plurality of first sub layers L1a and a plurality of second sub layers L1b are alternately stacked.

Compared with the alloy layer L1 shown in FIG. 10, the alloy layer L1′ shown in FIG. 11A and the alloy layer L1″ shown in FIG. 11B may each further include the plurality of first sub layers L1a including pure Al. Therefore, when a thickness of the alloy layer L1 shown in FIG. 10 is substantially equal to a thickness of alloy layers L1′ and L1″ shown in FIGS. 11A and 11B, the alloy layers L1′ and L1″ may have an elastic limit relatively greater than the elastic limit of the alloy layer L1 shown in FIG. 10, while having a resistivity relatively lower than the resistivity of the alloy layer L1.

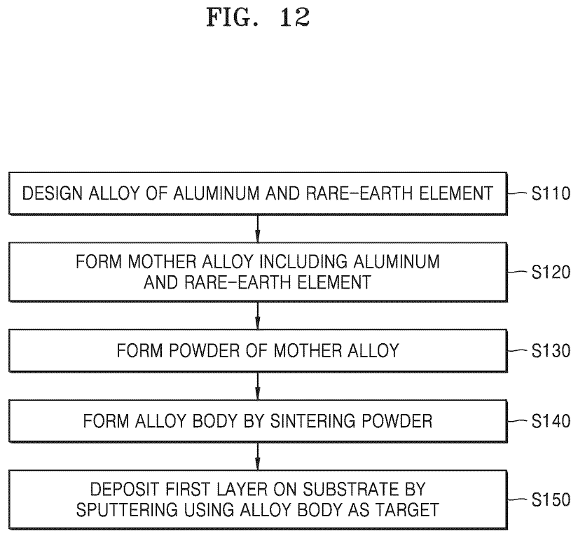

FIG. 12 is a flowchart illustrating a method of manufacturing the alloy layer L1, according to an embodiment.

A method of manufacturing a stretchable display apparatus, according to an embodiment, may include forming the first island portions 11 and the first bridge portions 12 each connecting the first island portions 11 disposed adjacent to each other and forming the wirings WL (see FIG. 9) arranged in the first bridge portion 12.

As described above, the wirings WL arranged in the first bridge portions 12 may have the structure of the conductive layer SCL (see FIG. 10). The wirings WL arranged in the first bridges 12 may each include the alloy layer L1 (see FIG. 10) including the alloy of Al and the Rare-earth element. The forming of the wirings WL may include forming the alloy layer L1. In an embodiment, the forming of the alloy layer L1 may be performed by a sputtering method.

In an embodiment, the forming of the alloy layer L1 may include designing an alloy of Al and the rare-earth element (S110), forming a mother alloy including Al and the Rare-earth element (S120), forming powder of the mother alloy (S130), forming the alloy body by sintering the powder (S140), and depositing the alloy layer L1 on a substrate by sputtering using the alloy body as a target (S150).

First, in operation S110, elements and contents in composition of the alloy may be designed. In an embodiment, the alloy layer L1 to be finally formed may include a binary alloy and may have a composition formula of AlₐM_{b}. Here, M may include at least one rare-earth element selected from among Y, Sm, Ce, and La. “a” and “b” each indicate the atomic percent (at %) of each element with reference to the total atomic weight of the alloy layer L1, and the sum of “a” and “b” may be 100. In an embodiment, “a” may be at least about 90 but not more than about 96, and “b” may be at least about 4 but not more than about 10. In other words, with reference to the total atomic weight of the alloy layer L1, the content of Al may be at least about 90 at % but not more than about 96 at %, and the content of the rare-earth element M may be at least about 4 at % but not more than about 10 at %. A composition of a target may be designed with reference to a composition of the alloy layer L1 to be finally formed.

Next, in operation S120, the mother alloy may be formed using a high-purity raw material. For example, a vacuum induction melting (VIM) method and the like may be used to form the mother alloy.

In operation S130, powder of the mother alloy may be formed. The mother alloy may be

powdered under a highly clean state. Atomizing methods, e.g., an electrode induction gas atomization (EIGA) method, may be used to form the powder. A size of particles of the powder may be from about 30 μm to about 50 μm.

In operation S140, the alloy body may be formed by sintering the powder. Through the sintering, the alloy body having a uniform composition may be formed. For example, a spark plasma sintering (SPS) process, a hot isostatic pressing (HIP) process, and the like may be used to form the alloy body. The alloy body may be processed into a size suitable for a target of the sputtering process.

In operation S150, the sputtering process may be performed on the alloy body as the target. The alloy layer L1 may be deposited on the substrate through the sputtering process. For example, a DC-magnetron sputtering method and the like may be used in the sputtering process.

A microstructure and mechanical properties of the alloy layer L1 may vary depending on conditions of the sputtering process. The sputtering process may be performed at a low temperature that is as low as a room temperature (RT). In an embodiment, a temperature of the substrate on which the alloy layer L1 is deposited may increase during the sputtering process, and therefore, a sputtering substrate may be cooled down such that a temperature of the sputtering substrate is maintained within a certain temperature range. In an embodiment, the temperature of the sputtering substrate may be about the room temperature RT or higher but lower than about 150° C. The temperature of the sputtering substrate may be about the RT or higher but not higher than about 80° C. When the temperature of the sputtering substrate is higher than about 150° C., recrystallization or phase separation may occur.

In an embodiment, the sputtering process may be performed at a power density of about 4 W/cm² or higher but not more than about 5 W/cm². The power density of the sputtering process may have influences on the temperature of the sputtering substrate. As the power density of the sputtering process increases, the temperature of the sputtering substrate may increase. When the power density of the sputtering process is lower than about 4 W/cm², a density of the film deposited may decrease, and a time period of deposition may increase, and the productivity may be degraded. When the power density of the sputtering process is higher than about 5 W/cm², recrystallization or phase separation may occur.

In an embodiment, the sputtering process may be performed under a deposition pressure of about 1 mTorr and more but not more than about 3 mTorr. The sputtering process may be performed under a deposition pressure of about 1 mTorr and more but not more than about 2 mTorr. The deposition pressure may vary depending on an amount of inert gas such as argon (Ar) introduced into a vacuum chamber in which the sputtering process is performed. When the deposition pressure is within the aforementioned range, a high-density alloy layer deposited by a layer-by-layer method and without a columnar structure may be formed. When the deposition pressure is less than about 1 mTorr, a time period of deposition may increase, and the productivity may be degraded. When the deposition pressure is greater than about 3 mTorr, an alloy layer having a columnar structure may be formed due to an island growth. The alloy layer L1 having a high-density microstructure without the columnar structure, compared with the alloy layer L1 having a microstructure including the columnar structure, may have extraordinary properties (e.g., mechanical properties).

The alloy layer L1 formed by adjusting the conditions in the sputtering processes, i.e., the power density in the sputtering process, the deposition pressure, and the temperature of the substrate, within the aforementioned range, may include an amorphous alloy, and may have a high-density fine structure without columnar structure.

In an embodiment, an elastic limit of the alloy layer L1 may be at least about 2%. The elastic limit of the alloy layer L1 may be at least about 2% but not more than about 3%. The elastic limit of the alloy layer L1 may be at least about 2.1% but not more than about 2.8%.

In an embodiment, a yield strength of the alloy layer L1 may be at least about 1.0 GPa but not more than about 1.5 GPa. The yield strength of the alloy layer L1 may be at least about 1.2GPa but not more than about 1.4 GPa.

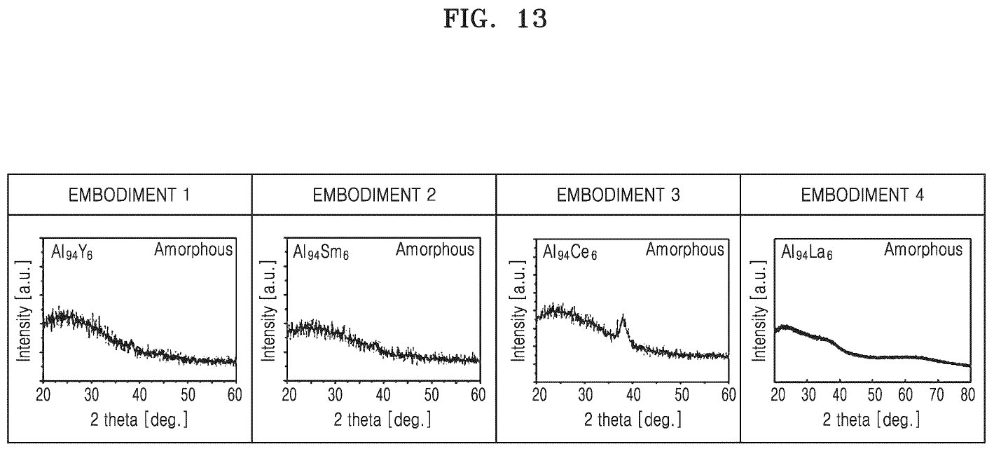

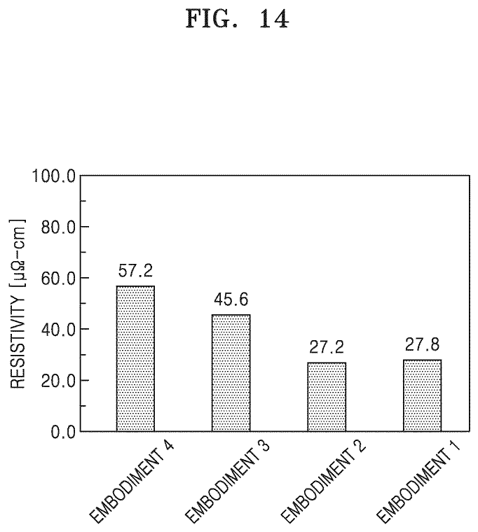

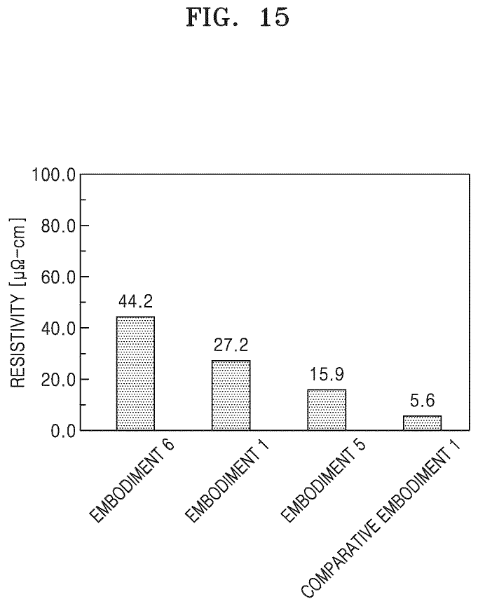

FIG. 13 illustrates a result of X-ray diffraction (XRD) of the alloy layer L1 according to an embodiment; and FIGS. 14 and 15 are graphs showing results of measuring the resistivity of the alloy layer according to an embodiment.

Referring to FIGS. 13 to 15, in embodiments 1 to 6, alloy layers including Al and the rare-earth element according to an embodiment having different types and contents of the rare-earth elements. An alloy layer having a thickness of about 300 nm was deposited by a DC-magnetron sputtering method at a low temperature on a silicon wafer substrate using the alloy body formed by powdering and sintering the mother alloy as a target. The sputtering process was performed under the conditions of the temperature of the sputtering substrate of RT or higher but not higher than 80° C., the power density of 4 W/cm² or higher but not higher than 5 W/cm², and the deposition pressure of 1 mTorr or higher but not higher than 2 mTorr. An alloy layer including Al and Y and having a composition formula of Al₉₄Y₆ was formed in embodiment 1, an alloy layer including Al and Sm and having a composition formula of A₉₄Sm₆ was formed in embodiment 2, an alloy layer including Al and Ce and having a composition formula of Al₉₄Ce₆ was formed in embodiment 3, and an alloy layer including Al and La and having a composition formula of Al₉₄La₆ was formed in embodiment 4. Alloy layers of Al and Y, which includes Y that is the rare-earth element used in embodiment 1, were formed in embodiment 5 and embodiment 6. An alloy layer having a composition formula of Al₉₆Y₄ was formed in embodiment 5, and an alloy layer having a composition formula of Al₉₂Y₈ was formed in embodiment 6.

An Al layer having a thickness of about 300 nm was formed in a comparative embodiment 1.

XRD analysis was performed on the alloy layers formed in embodiments 1 to 4. A result thereof were shown in FIG. 13.

Referring to FIG. 13, it is found that the alloy layers formed in embodiments 1 to 4 have amorphous phases in which peaks are not found. Accordingly, it is known that an alloy including Al and one of Y, Ce, Sm, and La as the rare-earth element in a content of about 4 at % to about 10 at % may have an amorphous phase.

Resistivity was measured with respect to the alloy layers formed in embodiments 1 to 6 and an Al layer in comparative embodiment 1. The resistivity was measured in a 4-point probe (4PB) method. A result thereof was shown in FIGS. 14 and 15. FIG. 14 is a graph showing a result of comparing resistivity of the alloy layers in embodiments 1 to 4, and FIG. 15 is a graph showing a result of comparing resistivity of the alloy layers in embodiments 1, 5, 6, and comparative embodiment 1.

Referring to FIG. 14, it is seen that the alloy layers in embodiments 1 to 3 have resistivity of 10 μΩ·cm or greater but less than 50 μΩ·cm. More particularly, it is seen that the alloy layers in embodiments 1 and 2 have a resistivity of about 10 μΩ·cm or greater but less than 30 μΩ·cm. Accordingly, it is seen that the resistivity characteristics of the alloy layers vary according to types of the rare-earth element. It is seen that the resistivity increase in the order of the alloy layer including Y or Sm, the alloy layer including Ce, and the alloy layer including La.

Referring to FIG. 15, it is found that the alloy layers in embodiments 1, 5, and 6 have resistivity of 10μΩ·cm or greater but less than 50 μΩ·cm. More particularly, it is seen that the alloy layer in embodiment 5 has a resistivity of about 10 μΩ·cm or greater but less than 25 μΩ·cm, and the alloy layer in embodiment 1 has a resistivity of about 10 μΩ·cm or greater but less than 30 μΩ·cm. It is seen that the alloy layer in comparative embodiment 1 has a resistivity less than about 10 μΩ·cm. Accordingly, it is found that the resistivity of the alloy layer decreases as the content (at %) of the rare-earth element decreases, even when the alloy layer includes a same rare-earth element (Y). By adjusting the content of the rare-earth element in the alloy, the alloy layer of Al and the rare-earth element having a resistivity similar to the resistivity of the pure Al layer may be formed. In an embodiment, when the alloy layer includes an alloy having a composition formula of AlₐY_{b} (94≤a≤96, 4≤b≤6), the alloy layer may have a resistivity of 10 μΩ·cm or greater but less than 30 μΩ·cm.

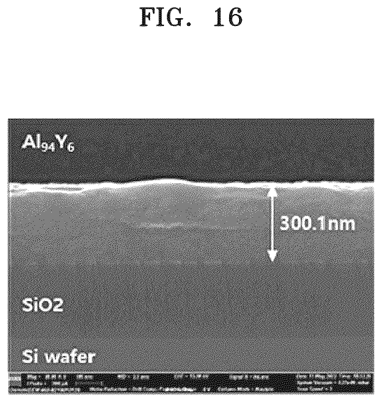

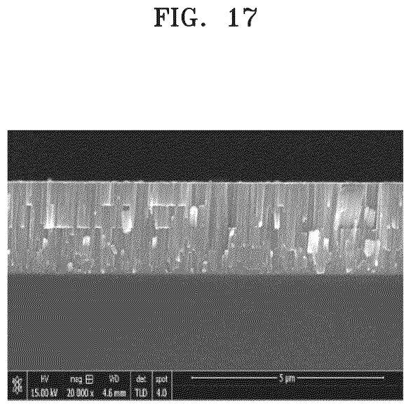

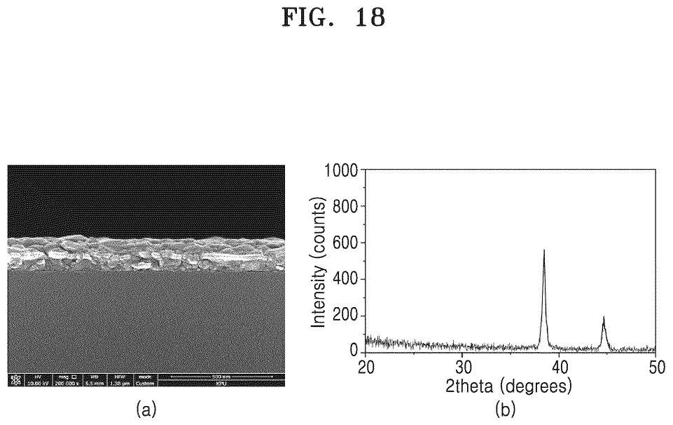

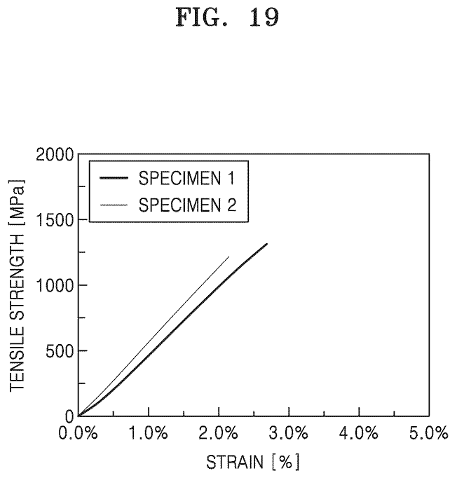

FIG. 16 illustrates a microstructure of an alloy layer according to an embodiment, FIG. 17 illustrates a microstructure of an alloy layer according to a comparative embodiment, and FIG. 18 illustrates a microstructure of an alloy layer according to Comparative Example and a result of performing XRD analysis. FIG. 19 is a graph showing a result of measuring an elastic limit of an alloy layer according to an embodiment.

Referring to FIGS. 16 to 19, in embodiment 1, an alloy layer of Al and the rare-earth element, according to an embodiment, was manufactured. An alloy layer having a thickness of about 300 nm was deposited by a DC-magnetron sputtering method at a low temperature on a silicon wafer substrate using the alloy body formed by powdering and sintering the mother alloy as a target. The sputtering process was performed under the conditions of the temperature of the sputtering substrate of RT or higher but not higher than 80° C., the power density of 4 W/cm² or higher but not higher than 5 W/cm², and the deposition pressure of 1 mTorr or higher but not higher than 2 mTorr. In embodiment 1, an alloy layer of Al and Y having a composition formula of Al₉₄Y₆ was formed.

An Al layer having a thickness of about 300 nm was formed in comparative embodiment 1.

In comparative embodiments 2 and 3, alloy layers of Al and the rare-earth element under conditions of sputtering process different from the conditions of sputtering process in embodiment 1. In comparative embodiment 2, sputtering was performed under a deposition process condition higher than 3 mTorr, that is, 5 mTorr or higher but not higher than 8 mTorr. In addition, in comparative embodiment 3, sputtering was performed at a condition of a power density higher than 5 W/cm². During the sputtering process, the temperature of the sputtering process was higher than 150° C. (unmeasurable). In comparative embodiments 2 and 3, an alloy layer of Al and Y having a composition formula of Al₉₄Y₆ was formed.

FIG. 16 illustrates a result of observation on a microstructure of the alloy layer in embodiment 1 using a focused ion beam-scanning electron microscope (FIB-SEM), and FIG. 17 illustrates a result of observation on a microstructure of the alloy layer in Comparative Example 2 using a FIB-SEM. (a) of FIG. 18 illustrates a result of observation on a microstructure of the alloy layer in Comparative Example 3 using a FIB-SEM, and (b) of FIG. 18 illustrates a result of XRD analysis on the alloy layer in Comparative Example 3.

Referring to FIGS. 16 to 18, it is seen that the alloy layer in embodiment 1 has an amorphous phase and has a high-density microstructure that is columnar-free. In addition, it is also seen that a surface of the alloy layer in embodiment 1 has a vein pattern. On the other hand, it is seen that the alloy layer in comparative embodiment 2 has an amorphous phase but has a microstructure that is columnar. In addition, it is found that the alloy layer in comparative embodiment 3 does not have an amorphous phase but has a crystalline structure.

A tensile experiment was performed on the alloy layer (specimen 1, specimen 2) in embodiment 1 and the Al layer in comparative embodiment 1. The tensile experiment was performed by a method of fabricating the specimen by patterning the alloy layer or the Al in a dog-bone shape by using a focused ion beam (FIB) method and performing in-situ measurement and recording a result of experiment on the specimen by using a scanning electron microscope (SEM) in which a Picoindenter is mounted. A result thereof is shown in Table 1 and FIG. 19.

TABLE 1

| | Elastic limit (%) | Yield strength [MPa] |
|---|---|---|
| Embodiment 1—Specimen 1 | 2.68 | 1,307 |
| Embodiment 1—Specimen 2 | 2.14 | 1,211 |
| Comparative embodiment 1 | 0.2 | 124 |

Referring to Table 1 and FIG. 19, the specimens in embodiment 1 did not undergo plastic deformation, and were broken during elastic deformation. An elastic limit in comparative embodiment 1 was low at 0.2%, while elastic limits in embodiment 1 were at 2.14% (specimen 2) and 2.68% (specimen 1) which is higher than that of the comparative embodiment 1. That is, it is seen that the alloy layer in embodiment 1 has a high elastic limit that is about ten times or greater the elastic limit of the Al layer in comparative embodiment 1. In addition, a yield strength of the Al layer in comparative embodiment 1 was at 124 MPa, while a yield strength of the alloy layer in embodiment 1 was at 1,307 MPa (specimen 1) and 1,211 MPa (specimen 2) which is higher than that of the comparative embodiment 1. That is, it is seen that the alloy layer in embodiment 1 has a yield strength about ten times a yield strength of the Al layer in comparative embodiment 1.

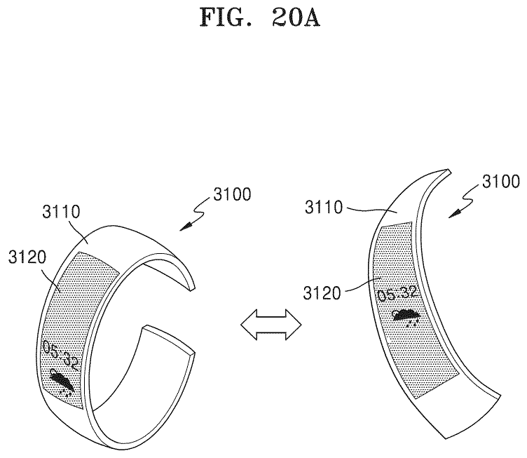

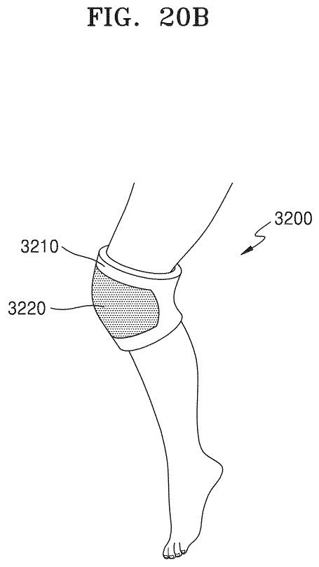

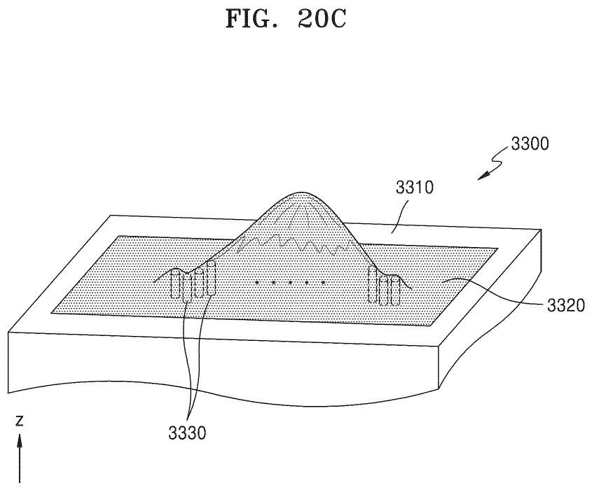

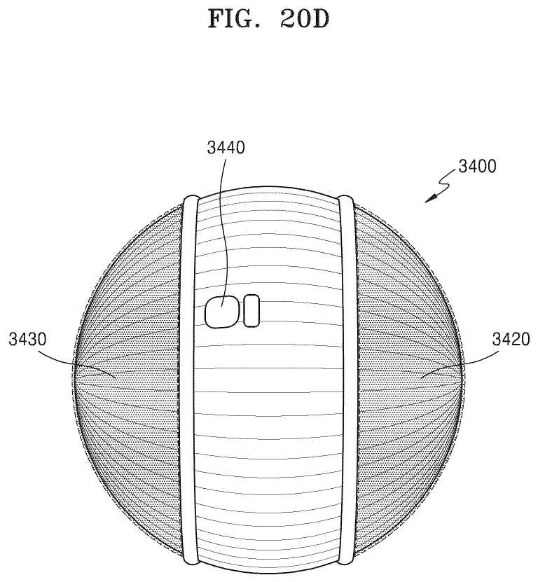

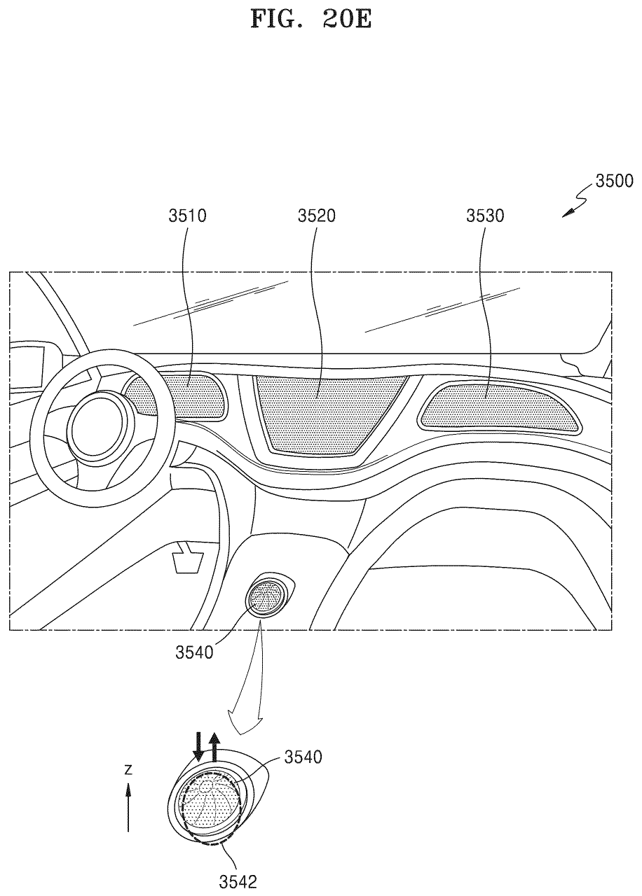

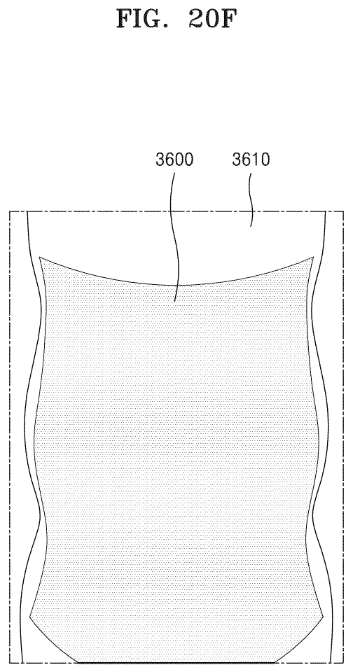

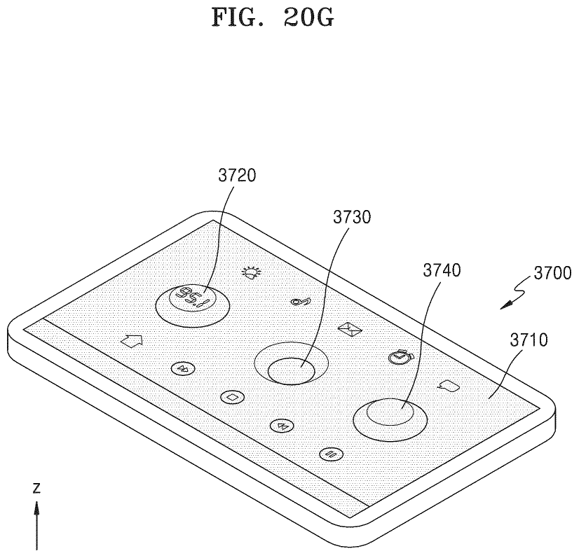

FIGS. 20A to 20G are perspective views schematically illustrating embodiments of an electronic device including the stretchable display apparatus 1 according to an embodiment.

The stretchable display apparatus 1 according to the aforementioned embodiments may be used in various electronic devices configured to provide images. Here, an electronic device indicates a device in which electricity is used and which may be configured to provide certain images.

Referring to FIG. 20A, the stretchable display apparatus 1 according to an embodiment may be used for a wearable electronic device 3100 wearable on a body of a user. The wearable electronic device 3100 may include a body unit 3110 and a display unit 3120 provided in the body unit 3110. The stretchable display apparatus 1 according to embodiments may be used as the display unit 3120 of the wearable electronic device 3100. The wearable electronic device 3100 shown in FIG. 20A may be modified. In an embodiment, the wearable electronic device 3100 may be used as a smartphone or a smartwatch according to selection of a user.

FIG. 20B illustrates a medical electronic device 3200. In an embodiment, the medical electronic device 3200 may include a body unit 3210 and an emission unit 3220. The stretchable display apparatus according to embodiments may be used as the emission unit 3220 of the medical electronic device 3200. The emission unit 3220 may be configured to emit light in a certain wavelength band (e.g., infrared ray, visible ray, and the like) to a body of a patient. In an embodiment, the body unit 3210 may include a stretchable fiber material, and may have a structure wearable on a user of the emission unit 3210.

FIG. 20C illustrates an educational electronic device 3300. In an embodiment, the educational electronic device 3300 may include a display unit 3320 provided in a frame 3310. The display unit 3320 may use the stretchable display apparatus according to embodiments. Images such as sea with waves, mountains covered by snow, or volcanoes with overflowing lava may be provided through the display unit 3320, and, in this case, the display unit 3320 may extend in a height direction (e.g., the z direction) in reflection of a height of the wave, the mountain, or the volcano. In some embodiments, a portion of the display unit 3320 may have consecutive changes in a height thereof in a direction in which the lava flows, to thereby three-dimensionally represent movement of the lava. The educational electronic device 3300 may include a plurality of pins (or stroke units) 3330 arranged at a rear surface of the display unit 3320 such that the display unit 3320 extends in the height direction. As the plurality of pins 3330 move in the third direction (e.g., the z direction or the-z direction), images expressed by the display unit 3320 may be implemented to have three-dimensional heights. Although the educational electronic device 3300 is described with reference to FIG. 20, the use of the educational electronic device 3300 will not be limited as long as the educational electronic device 3300 provides certain image information.

Although the electronic device having a variable shape is described with reference to FIGS. 20A to 20C, the embodiments are not limited thereto. Like in the following embodiments, the stretchable display apparatus 1 according to the embodiments may be used for an electronic device in which a portion that displays an image (e.g., a screen) is fixed.

FIG. 20D illustrates a robot 3400 as an electronic device according to an embodiment. The robot 3400 may be configured to recognize movements or objects by using a camera unit 3440, and may be configured to display certain images to the user through display units 3420 and 3430. In some embodiments, the stretchable display apparatuses according to an embodiment may extend in various directions as described above, and thus may be assembled to a body frame having a hemispherical shape, and accordingly, the robot 3400 may have the display units 3420 and 3430 having a hemispherical shape.

FIG. 20E illustrates a vehicle display apparatus 3500 as an electronic device according to an embodiment. The vehicle display apparatus 3500 may include a cluster 3510, a center information display (CID) 3520, and/or a passenger display (also referred to as a co-driver display). As the stretchable display apparatus 1 according to embodiments may extend in various directions, and may be used for the cluster 3510, the CID 3520, and/or the co-driver display 3530 regardless of a shape of an inner frame of the vehicle.

Although FIG. 20E illustrates that the cluster 3510, the CID 3520, and/or the co-driver display are separated from one another, the embodiments are not limited thereto. In another embodiment, at least two units selected from among the cluster 3510, the CID 3520, and the co-driver display may be integrally connected to each other.

In some embodiments, the vehicle display apparatus 3500 may include a button 3540 configured to display certain images. Referring to an enlarged image in FIG. 20E, the button 3540 having a hemispherical shape may include an object 3542 configured to provide a feeling of using the button while the object 3542 moves in the z direction or the −z direction; and the stretchable display apparatus disposed on the object 3542. In some embodiments, when the object 3542 has a three-dimensionally rounded surface, the stretchable display apparatus may also have a three-dimensionally rounded surface.

FIG. 20F illustrates that the electronic device according to an embodiment includes an electronic device for advertisement or exhibitions 3600. In some embodiments, the electronic device for advertisement or exhibitions 3600 may be mounted onto a structure 3610 that is fixed, e.g., as a wall or a pillar. When the structure 3610 includes an uneven surface as shown in FIG. 20F, the electronic device for advertisement or exhibitions 3600 may also be arranged along the uneven surface of the structure 3610. In some embodiments, the electronic device for advertisement or exhibitions 3600 may be mounted onto the structure 3610 by using a heat shrinkage film and the like.

FIG. 20G illustrates that an electronic device according to an embodiment is a controller 3700. The controller 3700 may include image-type buttons. For example, the controller 3700 may include a first button area 3720, a second button area 3730, and a third button area 3740, which include some portions of the display unit 3710 protruding in the z direction or protruding in the −z direction (or being recessed in the z direction). In some embodiments, the first button area 3720 and the third button area 3740 may protrude in the z direction, and the second button area 3730 may protrude in the −z direction (or be recessed in the z direction).

According to an embodiment, a display apparatus that may prevent damage caused by concentration of stress and may be stretched/contracted in various directions may be provided. However, the scope of the embodiments are not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A stretchable display apparatus comprising a display area and a non-display area outside the display area, the stretchable display apparatus comprising:
a plurality of island portions arranged in the display area and disposed to be spaced apart from one another;
a plurality of bridge portions each connecting adjacent island portions among the plurality of island portions; and
a plurality of wirings arranged in the plurality of bridge portions, and
wherein each of the plurality of wirings includes a first layer including an alloy of aluminum and a rare-earth element.

2. The stretchable display apparatus of claim 1, wherein the first layer includes an amorphous alloy layer.

3. The stretchable display apparatus of claim 1, wherein the rare-earth element includes at least one of yittrium (Y), samarium (Sm), cerium (Ce), and lanthanium (La).

4. The stretchable display apparatus of claim 1, wherein a content of the rare-earth element is at least 4 at % but not more than 10 at % with respect to a total atomic weight of the first layer.

5. The stretchable display apparatus of claim 1, wherein a content of the aluminum is at least 90 at % but not more than 96 at % with respect to a total atomic weight of the first layer.

6. The stretchable display apparatus of claim 1, wherein a resistivity of the first layer is at least 10 μΩ·cm and less than 50 μΩ·cm.

7. The stretchable display apparatus of claim 1, wherein an elastic limit of the first layer is at least 2.0% but not more than 3.0%.

8. The stretchable display apparatus of claim 1, wherein a yield strength of the first layer is at least 1.0 GPa but not more than 1.5 GPa.

9. The stretchable display apparatus of claim 1,
wherein each of the plurality of wirings further comprises:
a second layer disposed under the first layer; and
a third layer disposed over the first layer,
wherein the second layer and the third layer comprise materials different from a material of the first layer, and
wherein the second layer and the third layer comprise a same material.

10. The stretchable display apparatus of claim 1,
wherein each of the island portions comprises:
a transistor including a semiconductor and a gate electrode;
an emission element electrically connected to the transistor; and
an electrode disposed between the gate electrode and the emission element,
wherein the electrode includes an alloy layer of aluminum and a rare-earth element.

11. A method of manufacturing a stretchable display apparatus comprising a display area and a non-display area outside the display area, the method comprising:
forming a plurality of islands arranged in the display area and disposed to be spaced apart from one another, and a plurality of bridge portions each connecting adjacent island portions from among the island portions; and
forming a plurality of wirings arranged in the plurality of bridge portions,
wherein the forming of the plurality of wirings comprises:
forming a first layer including an alloy of aluminum and a rare-earth element by a sputtering method.

12. The method of claim 11, wherein the forming of the first layer comprises:
forming a mother alloy comprising aluminum and a rare-earth element;
forming powder of the mother alloy;
forming an alloy body by sintering the powder; and
depositing a first layer on a substrate by sputtering using the alloy body as a target.

13. The method of claim 12, wherein a temperature of the substrate is at least RT and less than 150° C.

14. The method of claim 12, wherein the sputtering is performed at a power density of at least 4 W/cm² but not more than 5 W/cm².

15. The method of claim 11, wherein the first layer includes an amorphous alloy layer.

16. The method of claim 11, wherein the rare-earth element comprises at least one of yittrium (Y), samarium (Sm), cerium (Ce), and lanthanium (La).

17. The method of claim 11, wherein a content of the rare-earth element is at least 4 at % but not more than 10 at % with respect to a total atomic weight of the first layer.

18. The method of claim 11, wherein a content of the aluminum is at least 90 at % but not more than 96 at % with respect to a total atomic weight of the first layer.

19. The method of claim 11, wherein an elastic limit of the first layer is at least 2.0% but not more than 3.0%.

20. The method of claim 11, wherein a yield strength of the first layer is at least 1.0 GPa but not more than 1.5 GPa.
